(19) United States
(12) Patent Application Publication
(10) Pub. No.: US 2026/0236625 A1
(43) Pub. Date: Aug. 13, 2026

(54) System and Method for Quantitative Prioritization of Risk Reduction Activities through Home Hardening and Defensible Space in Fire Prone Urban Environments

(71) Applicant: Xylo Risk, Inc., Sonoma, CA (US)

(72) Inventors: Scott Farley, Boulder, CO (US); David Winnacker, Albany, CA (US)

(21) Appl. No.: 19/531,486

(22) Filed: Feb. 5, 2026

Related U.S. Application Data
(60) Provisional application No. 63/757,654, filed on Feb. 12, 2025.

(51) Int. Cl. G06F 30/10

(52) U.S. Cl. CPC G06F 30/10

(57) ABSTRACT

A method and/or system for evaluation of a home hardening and defensible space prioritization plan that autonomously evaluates urban conflagration risk and recommends homes that provide the greatest community benefit once home hardening and defensible space requirements are met. A cloud-enabled user interface may provide decision support to fire agencies and community structural fire inspection specialists charged with implementing wildfire risk reduction measures.

### CROSS REFERENCE TO RELATED APPLICATIONS

This application claims priority to a co-pending U.S. Provisional Patent Application Ser. No. 63/757,654 filed Feb. 12, 2025 entitled “System and Method for Quantitative Prioritization of Risk Reduction Activities through Home Hardening and Defensible Space in Fire Prone Urban Environments”, the entire contents of which are hereby incorporated by reference.

### TECHNICAL FIELD

This document relates to a home hardening and defensible space prioritization plan development method and/or system that autonomously evaluates urban conflagration risk and recommends homes that provide the greatest community benefit once home hardening and defensible space requirements are met. A cloud-enabled user interface may provide decision support to fire agencies and community structural fire inspection specialists charged with implementing wildfire risk reduction measures.

### BACKGROUND

Wildfires are a large and growing problem, particularly in the Western United States, where thousands of residential and commercial properties are burned annually. As widespread development pushes communities deeper into fire-prone ecosystems, more homes and businesses are at risk of wildfire-related loss. Accurate prediction of damage at the structure level is critical to maintaining public safety, incentivizing risk mitigation efforts, and stabilizing residential insurance markets. Community wide Home Hardening and Defensible Space inspections and enforcement conducted by city agencies require effective prioritization to maximize community benefit.

Current wildfire risk models are insufficiently accurate to support insurance and local risk mitigation activities. Numerous residential insurance companies have withdrawn from the State of California due to the inability to accurately segment and price wildfire risk. Current risk reduction approaches at the local- and state-government levels are also not based on reliable modeling.

Existing wildfire risk assessment frameworks are widely used for public safety and insurance purposes, including underwriting and pricing. While these frameworks excel at predicting wildfire intensity based on vegetative fuel loads, they are incapable of effectively evaluating fire spread within the built environment-residential, commercial, and industrial structures. This gap is particularly critical in the Wildland Urban Interface (WUI), where tightly packed, traditionally wood-framed homes become urban fuels during Urban Conflagrations, such as those witnessed in the Palisades and Eaton Fires of 2025. In these scenarios, homes themselves become the primary source of fire spread, generating embers and convective heat that ignite neighboring structures. This Urban Conflagration Fire Model addresses this challenge by leveraging advanced, cloud-based computational power to simulate fire behavior in urban settings through complex, iterative calculations-offering a more accurate and comprehensive approach to assessing urban fire risks.

### SUMMARY OF PREFERRED EMBODIMENTS

This work describes a novel method and/or system for characterizing urban fire risk that is built explicitly to address the gaps in the existing tools and methodologies identified above.

A computer-implemented model simulates how fire moves through an urban environment, focusing on structure-to-structure fire transmission and ember spread, which are key factors in large-scale urban fires. The model uses real-world data about buildings, environmental conditions (such as wind and terrain), and fire dynamics to simulate how fire ignites and propagates over time and space. The simulation can be used for a variety of purposes, such as to visualize fire spread, or evaluate the effect of different treatment options such as home hardening or other mitigation strategies.

Among the goals of this approach are to:
a. Probabilistically capture the role of structure separation distance, ember travel, and environmental conditions on urban fire spread.
b. Incorporate the influence of home hardening and defensible space as key properties in determining the initiation and trajectory of fire spread through the built environment.
c. Enable generation and comparison of optimized treatment plans

More particularly, systems and methods for predicting a probability of wildfire spread for an urban environment may begin by first obtaining historical data for the urban environment, including structure data, defensible space, separation distance, ember travel, and environmental conditions. Next, a probabilistic estimate of an initiation and/or trajectory of fire spread is based on the historical data. A directed graph representing the urban environment is then created, where nodes represent structures and edges have attributes representing the historical data. The edges may include and one or more of separation distance, compass bearing between nodes, and slope. A fire spread model is then trained from the directed graph, the model accounting for probabilistic fire pathways, structure ignition, fire intensity, fire transmission, ember spread and ember ignition.

Wildfire spread prediction data may then be generated using the fire spread model, and used for optimizing fire risk reduction activities.

In some embodiments, the systems and methods are used for quantitatively characterizing and reducing wildfire-driven urban conflagration risk in fire-prone communities, including Wildland Urban Interface (WUI) environments. In many severe wildfire events, structure-to-structure fire transmission-including heat transfer and ember-driven ignition-becomes a dominant driver of loss within the built environment. The disclosed embodiments provide a computer-implemented framework that (i) constructs a computational representation of the built structures in a community, (ii) executes a probabilistic, time-evolving simulation of fire propagation through structures, and (iii) produces actionable, resource-constrained prioritizations for mitigation activities that can be implemented by fire agencies, community inspectors, and other stakeholders.

In one aspect, a computer-implemented method obtains urban environment data including, for example, building structure data, defensible space data, structure separation distance data, ember transport data, and environmental condition data (e.g., wind and terrain). Using at least a portion of the urban environment data, the method constructs a directed graph representing the built environment in which nodes correspond to building structures and edges correspond to potential fire transmission relationships between structures. In some embodiments, edge attributes include at least separation distance and at least one of compass bearing and slope, and may further include an indicator of whether a line segment between structures crosses a road or other feature relevant to transmission mechanisms.

In some embodiments, the method executes a probabilistic fire spread simulation over the directed graph to compute structure ignition likelihoods and fire progression over time. The simulation may incorporate multiple ignition and transmission mechanisms, including (a) radiant heating between nearby structures, (b) convective heating influenced by wind direction and wind speed, (c) understood or estimated impacts of terrain slope, (d) optional surface-fire spread behavior as applicable to the built environment and intervening features, and (e) ember launch, transport, deposition, and ember-based ignition.

In certain implementations, edges may be added between nodes only if the corresponding structures are within a predetermined distance threshold associated with heat-driven transmission; beyond such threshold, the simulation may continue to model fire spread via ember transport and deposition. Where roads or other non-burnable barriers are present, certain mechanisms (e.g., surface spread) may be reduced or disabled across an edge, while other mechanisms (e.g., radiant/convective heating and/or ember transport) may remain modeled across that same edge.

In some embodiments, the simulation models each ignited structure as having a time-varying fire intensity profile that changes as a function of time since ignition, such as including a ramp-up phase, a peak phase, and a decay phase. The fire intensity profile may be used to modulate the probability and/or magnitude of heat-driven transmission to neighboring structures and may also modulate the probability of ember generation and the expected distance distribution of ember transport. Ember trajectories may be simulated using prevailing wind conditions and, in some implementations, stochastic perturbations to represent variability in ember flight. Simulated ember deposition locations may be compared to building footprints or proximity thresholds to determine whether deposition triggers an ignition event.

In some embodiments, the likelihood that a target structure ignites is additionally determined using structure-specific receptivity or susceptibility factors. Such factors may include home hardening characteristics, defensible space characteristics, and/or an indicator of firefighter presence or protective intervention at or near a given structure. In certain embodiments, these factors adjust the probability of ignition from heat transfer and/or ember deposition. In addition, some implementations may model ambient embers originating from wildland fire pathways at a background rate, such that structures may ignite from ember deposition even without direct structure-to-structure heat transmission.

The outputs of the simulation may include wildfire spread prediction data such as, for each structure, an estimated ignition probability, a distribution of ignition times, or other community-scale risk metrics. In some embodiments, prediction data is generated using an ensemble of simulation runs, and per-structure ignition probability may be computed as a frequency of ignition across the ensemble. In certain implementations, the simulation output may further be processed to identify or infer ignition dependency chains or transition relationships (e.g., dependency trees or transition models) indicating how upstream ignitions contribute to downstream ignitions across the community representation.

In another aspect, the disclosed embodiments determine a resource-constrained treatment plan that prioritizes and/or selects mitigation actions to reduce community risk. In some implementations, the treatment plan is produced by iteratively selecting candidate mitigation actions—such as home hardening, defensible space improvement, and/or firefighter deployment and suppression placement—to maximize a risk reduction metric derived from the wildfire spread prediction data, subject to one or more constraints (e.g., a predefined number of structures to be treated, budget constraints, and/or limited suppression resources). The treatment plan may be output as a prioritized list, map visualization, or other decision-support format suitable for implementation and tracking.

In another aspect, a system for optimizing urban conflagration risk reduction activities comprises one or more processors and memory storing instructions that, when executed, cause the system to: ingest built environment and environmental condition data; construct a directed graph representation of the community; execute a probabilistic multi-mechanism fire spread simulation incorporating heat transfer and ember propagation; generate wildfire spread prediction data; and compute a resource-constrained mitigation prioritization or treatment plan. In certain embodiments, the system includes an evaluation module, a fire behavior simulation module, and a treatment optimization module, and may further include a user interface that renders predicted risk and recommended actions for one or more stakeholders. The system may be implemented on local computing hardware and/or a cloud computing platform, including for scalable simulation runs and scenario analysis under varying environmental conditions and mitigation states.

In yet another aspect, a non-transitory computer-readable medium stores instructions that, when executed by one or more processors, cause performance of any of the methods described herein.

In some implementations, the model may be further used for (a) evaluating home hardening, defensible space, and fire suppression capabilities based on the wildfire spread prediction data and/or (b) determining a treatment plan by iteratively selecting home hardening, defensible space, and fire suppression locations to maximize risk reduction within the urban environment, based on one or more fire spread pathways.

A system for optimizing urban conflagration fire risk reduction activities in a resource-constrained environment may include a number of components, including computer memory holding computer program instructions executed by one or more hardware processors for optimizing urban conflagration fire risk reduction activities in a resource-constrained environment. The computer program instructions may include (a) an evaluation module configured to generate and evaluate home hardening, defensible space, and fire suppression capabilities based on urban fire risk data, (b) a fire behavior simulation module that computes fire spread attributes across a community including at least fire spread pathways, urban fuel load, topography and community risk, and (c) a treatment optimization module that iteratively selects home hardening, defensible space, and fire suppression locations as provided by the evaluation module to maximize urban conflagration risk reduction within a predefined number of structures. Such a system may autonomously select and evaluate of treatment opportunities based on fire spread pathways, urban fuel load, topography, and community risk as provided by the fire behavior simulation module.

The methods and systems may be implemented on any suitable physical or cloud computing platform that process input data, provide and operate the simulation model, the user interfaces, and other processes and features described herein.

### BRIEF DESCRIPTION OF THE DRAWINGS

FIG. 1 illustrates an example system for implementing the fire behavior model.

FIG. 2 illustrates an example process flow at a high level

FIG. 3 is an example curve of relative fire intensity as a function of simulation time.

FIG. 4 is an example curve of a fire transmission probability modifier as a function of node separation distance, used to represent the decay of radiant heating.

FIG. 5 shows wind direction effect on fire transmission probability as a function of the alignment (in degrees) between nodes and the prevailing wind direction.

FIG. 6 shows composite probability of fire transmission incorporating both distance decay (radiative heating) and wind alignment (convective heat).

FIG. 7 is an example of home hardening, defensible space, and firefighter presence effect on ignition probability as a function of source to target node distance.

FIG. 8 shows an example of how these characteristics work together to facilitate fire spread between building nodes.

FIG. 9 shows modeled fire spread probability between four different edges.

FIG. 10 is an example of a resulting simulated ember deposition from a burning structure node for a given wind direction and built environment model.

FIG. 11 is an example simulation result showing ember deposition at varying levels of relative fire intensity for the same built environment.

FIG. 12 illustrates each iteration of a simulation loop, where the following steps are performed (reference numbers in parenthesis correspond to steps illustrated in the figure).

FIG. 13 is a graph of angular bearings between nodes for an example built environment.

FIG. 14 is a resulting wind direction effect assuming a 270-degree (west) wind for nodes in the synthetic graph.

FIG. 15 is an example of the resulting angular bearing in degrees between node pairs with a 30 m spread constraint.

FIG. 16 shows angular distance in meters between each pair of nodes in the example built environment.

FIG. 17 is a graph of the probability of ignition modulated according to that distance effect, representing capacity for radiant heat transfer to transmit fire from one building to another.

FIG. 18 illustrates an example of the composite fire transmission probabilities for a west wind.

FIG. 19 shows example composite fire transmission probabilities for a north wind.

FIG. 20 shows example composite fire transmission probabilities for an east wind.

FIG. 21 shows an example transmission sequence (without embers) through the synthetic graph for a west wind.

FIG. 22 shows an example sequence of ignitions in the synthetic graph for an east wind direction.

FIG. 23 shows the probability of ignition for each structure over an ensemble of 10,000 different simulations under a south wind, excluding embers.

FIG. 24 shows the node-to-node distance of structures that ignited at least once during the simulation of FIG. 23.

FIG. 25 is an plot of ember trajectories originating from different source nodes under a north wind scenario.

FIG. 26 illustrates burn probability for a neighborhood under a north wind incorporating both heat-based fire transmission and ember transport and deposition.

FIG. 27 illustrates burn probability for the same neighborhood under the same wind events, but where each structure has been at least partially hardened to resist ember-based ignitions.

FIG. 28 is an example work flow for a fire spread simulation.

FIG. 29 is an example workflow for building a graph (steps 2804-2810 of FIG. 28).

FIG. 30 is an example workflow for each simulation (steps-2826 of FIG. 28).

FIG. 31 is an example process flow for combining simulations.

FIG. 32 is a Traditional Fire Development curve (from the NIST).

FIG. 33 shows fire development curves for mitigated (fire-resistant) and unmitigated (basic) structures.

FIG. 34 shows radiant heat fire transmission parameter as a function of node separation distance.

FIG. 35 shows Convective heat fire transmission parameter as a function of bearing.

FIG. 36 is a workflow for an example ember transport module.

FIG. 37 is a table of parameters that may be configurable by the model developer.

### DETAILED DESCRIPTION OF PREFERRED EMBODIMENTS

### Introduction

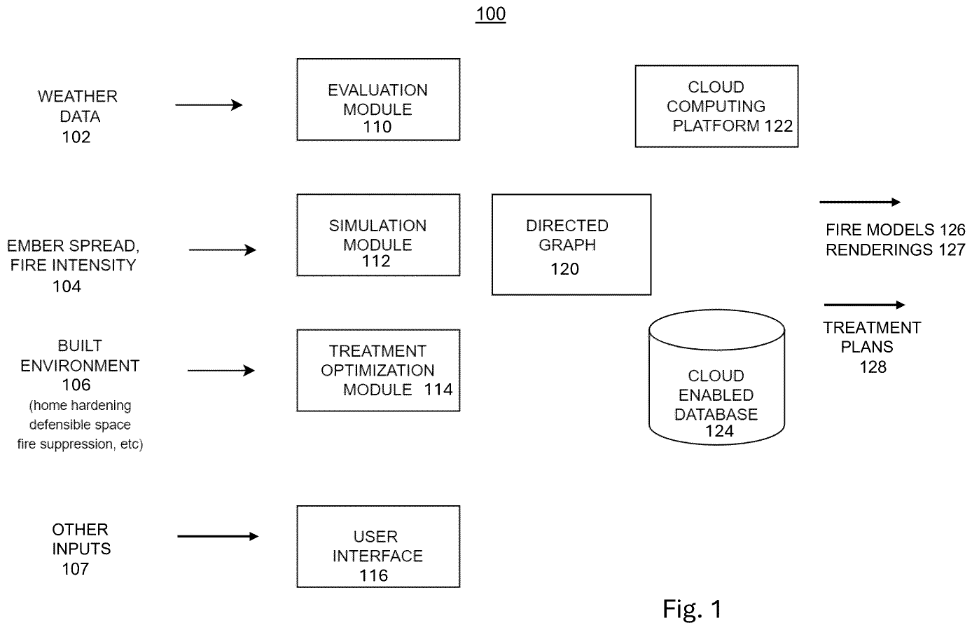

FIG. 1 illustrates an example system 100 for implementing the fire behavior model. The system accepts inputs such as weather data 102, ember spread and fire intensity data 104, built environment data 106 and other data 107. System components include an evaluation module 110, simulation module 112, treatment optimization module 114, user interface 116, directed graph 120, cloud computing platform 122 and cloud enabled database 124. Outputs may include fire models 126 and visual renderings thereof 127, and/or treatment plans 128 based on the models 126 as well as other outputs. The system 100 and related processes performed by the system are described in more detail in the sections that follow.

### Model Overview

### 1.1 Fire Spread Between Structures

An example fire spread model 126 relies on data about the built environment 106, including for example:
a. Home Hardening: Each building (or other element of the built environment) has a hardening indicator that determines how easily it ignites.
b. Defensible Space: The model factors the amount of defensible space the specific building has around it.
c. Firefighter Presence: If a firefighter is assigned to a building, the chance of ignition decreases, reflecting firefighting efforts to protect the structure.

Fire can spread from one building to another through radiant and convective heat. This transmission depends on:
a. Distance Between Buildings: Closer buildings are more likely to spread fire between them.
b. Wind: Wind can carry flames and heat, making it easier for fires to spread in the direction of the wind.
c. Slope: Fires spread faster uphill, so buildings located uphill from an ignited structure are at greater risk.

### 1.2. Ember Spread

In large urban fires, embers can be carried by wind over long distances, igniting new structures far from the main fire front. The model also uses ember spread and fire intensity data 104 as follows:
a. Ember Launch: When a building is on fire, there's a chance that it will launch embers into the air. The probability of launching embers increases as the fire intensifies.
b. Ember Trajectory: Once an ember is launched, its trajectory is influenced by the wind speed and direction.
c. Ember Deposition and Ignition: If an ember lands on or near another building, there's a chance it will ignite that building. The chance of downstream ignition depends on that building's home hardening and defensible space characteristics.

Additionally, structures can be ignited by embers originating from wildland fuels at a background (“ambient”) rate, where the conditional probability of ignition after being exposed to a simulated ember is dependent on the home hardening and defensible space characteristics of that building.

### 1.3. Fire Intensity and Burn Time

The data representing each building may have an associated burn intensity curve that reflects how long it will burn once ignited. The burn time follows three phases:
a. Ramp-up: At the start, the fire slowly intensifies as the building ignites.
b. Peak Intensity: When the fire reaches its peak, the building is most likely to spread fire to nearby structures or launch embers.
c. Decay: After the peak, the building's fire intensity decreases until it burns out completely.

As a building burns, the chance of it igniting nearby structures decreases.

### 1.4. Firefighter Intervention

If firefighters are present at a building, other data 107 can be provided to the model that reduces the probability that the building will ignite, reflecting the protective actions taken by firefighters to defend structures. Firefighters can prevent ember ignitions and reduce the spread of fire from nearby buildings. The probability of firefighter success is dependent on the number of nearby structures.

### 1.5. High-Level Simulation Flow

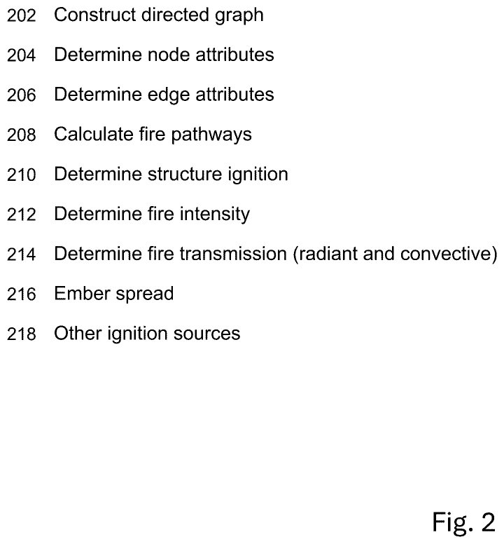

FIG. 2 illustrates an example process flow at a high level.

An initial set of steps in the process serve to set up a fire model 126 as a directed graph 120. The example process has multiple steps, each described below with reference to a corresponding numbered step in FIG. 2.

At (202), a directed graph is constructed to represent a particular built environment:

Node Attributes: Nodes are assigned attributes (204) indicating the presence of adequate defensible space (0/1), chapter 7A construction (0/1). Additionally, the graph can be configured to represent the presence of firefighters, where nodes also indicate whether a firefighter is present (0/1).

Edge Attributes: Edges are constructed (206) between all nodes within a certain distance, such as 30 m, of a target node. Edge attributes may include the distance between the two nodes, whether the node-to-node edge crosses a road, the compass bearing of the edge, and the slope between the two edges.

Fire Pathways: Fire pathways are calculated (208) such as by using Finney's MTT (see Finney, “Fire growth using minimum travel time methods” Canadian Journal of Forest Research, August 2002 https://doi.org/10.1139/x02-068) to determine where the fire is likely to enter the community. Nodes adjacent to the pathways are considered for ignition.

Initialization is the next phase, including Structure Ignition. Structures adjacent to the pathways are ignited (210); the probability of ignition may be modulated based on home hardening and defensible space.

Subsequently, fire spread is calculated and may involve using iterative simulation.

Fire Intensity (212): A point-in-time estimate of relative fire intensity based on relative time from ignition is determined. Fire intensity ramps up before decaying; the probability of igniting adjacent structures and casting long-distance embers is greatest at peak intensity.

Fire Transmission through Radiant and Convective Heating (214): The likelihood of fire spreading from an ignited building to its neighbors may be based on distance, wind, and slope.

Ember Spread (216): Embers launched from burning structures and carried by the prevailing wind are modelled; for example, embers that land adjacent to buildings may ignite those nodes.

Other Ignition Sources (218): Non-ignited buildings may catch fire due to heat transfer, ember landings, or ambient ember deposition (embers coming from the wildland).

The simulation steps 210-218 iterate until no more buildings are susceptible.

### 2.0 Directed Graph Detail

### 2.1 Set Up of the Directed Graph

Returning to step 202 in more detail, we model the built environment as a graph, (e.g., graph 120 in FIG. 1) where
a. is the set of nodes, representing structures in the environment.
b. is the set of edges representing possible paths for heat-driven fire transmission between structures.

In step 204, each node added to the directed graph 120 corresponds to a structure with centroid and is associated with attributes describing its ignitability, including:
a: Home hardening factor, reflecting the resistance of the structure to ignition.
b: Defensible space factor, reflecting the amount of vegetation clearance around the structure.
c: Firefighter presence indicator, where if a firefighter is present and otherwise.
d: Ignition state of the structure, where if the structure is ignited and \(S_i=0 \) if not.

In step 206, each edge connects two structures and, and is associated with the following parameters:
a: Distance between nodes and.
b: Wind factor influencing the transmission of convective heat from to, defined as: where is the difference in radians between the prevailing wind direction and the line connecting and.

An edge is only added between and if the distance between the two nodes is less than. If the distance between the nodes exceeds this threshold value, fire can spread between the two structures via ember propagation, but not via radiant and convective heating.

### 2.2 Initialization of Fire Spread Model

Using the fire pathways identified in step 208, a subset of nodes in the graph are considered as potential ignition candidates in step 210. The likelihood that these candidate nodes ignite is determined by several factors, including their home hardening, defensible space characteristics, and the presence of a firefighter at the location. We define the initial ignition probability as a function of these factors. As a preliminary formulation, the probability of initial ignition is given by:

a.

After calculating the initial ignition probability for each structure, we simulate whether a structure ignites by conducting a binomial trial. The ignition event is modeled as a Bernoulli process, where the probability of success (ignition) is. Specifically, for each structure, a binomial draw with one trial is performed to determine if ignition occurs.

The ignition is therefore defined probabilistically as:

a.

where indicates that the structure ignites, and indicates no ignition.

### 2.3 Heat Transmission Between Nodes

The overall heat transmission probability from structure node to structure node is given by the fire intensity at source structure, the conditions at the target structure and the conditions along the edge.

Fire Intensity (step 212)

For a burning structure node, a fire intensity curve describes how the fire intensity at a structure evolves over time. The intensity curve follows a three-phase model: a ramp-up phase, a peak intensity phase, and a decay phase. Let represent the fire intensity at time, where is the moment the structure ignites.

During the initial ramp-up phase, the fire intensity increases gradually as the fire spreads within the structure. This phase lasts for a time, after which the fire reaches its peak intensity. We model this phase as a linear increase in intensity:

Where:
is the maximum intensity the fire reaches,
is the time taken to reach the peak intensity.

Once the fire reaches peak intensity at time, the intensity remains constant for a duration. During this phase, the structure is burning at its maximum intensity:

a.

where is the duration for which the fire burns at its peak intensity.

After the peak intensity phase, the fire intensity begins to decay as the structure burns out. The decay phase lasts for a time, and we model this phase as a linear decrease in intensity:
where is the time it takes for the fire to completely burn out. At time, the fire intensity reaches zero.

The complete fire intensity curve is a piecewise function that describes the fire's behavior over time, combining the ramp-up, peak, and decay phases:

$$I ( t ) = \{ \begin{matrix}\frac{{I}_{peak}}{{T}_{ramp}} \cdot t & for 0 \leq t \leq {T}_{ramp} \\ {I}_{peak} & for {T}_{ramp} \leq t \leq {T}_{ramp} + {T}_{peak} \\ {I}_{peak} \cdot ( 1 - \frac{t - ( {T}_{ramp} + {T}_{peak} )}{{T}_{decay}} ) & for {T}_{ramp} + {T}_{peak} \leq t \leq {T}_{ramp} + \\ & {T}_{peak} + {T}_{decay} \\ 0 & for t > {T}_{ramp} + {T}_{peak} + {T}_{decay}\end{matrix}$$

This model captures the typical fire behavior for a structure, starting with a ramp-up phase, followed by a period of maximum intensity, and finally, a decay phase as the structure burns out.

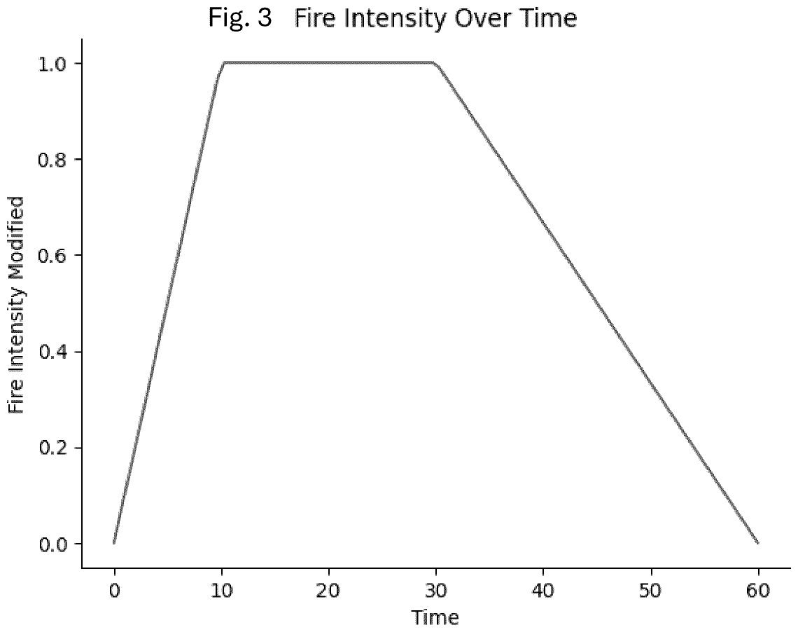

FIG. 3 is an example curve of relative fire intensity as a function of simulation time.

2.4 Radiative Heating and Decay with Distance (Step 214)

Radiative heating is a key mechanism through which fire spreads between structures. The intensity of radiative heat decreases with distance, meaning structures that are further apart are less likely to ignite due to radiative heat transfer. The model incorporates this effect via a distance decay model, where the probability of fire transmission declines exponentially with distance between the source and target structure. Structures that are closer than about 30 feet (centroid-to-centroid) receive the full value of the radiant heating, while structures further away receive only a portion of the heat produced by structure.

Mathematically, we define the distance decay function for radiative heating as:

$${f}_{decay} ( {d}_{ij} ) = \{ \begin{matrix}1 & if {d}_{ij} < 7 \\ exp ( - 0.1 \cdot {d}_{ij} + 1 ) & if {d}_{ij} \geq 7\end{matrix}$$

Where is the distance between the node and node in meters.

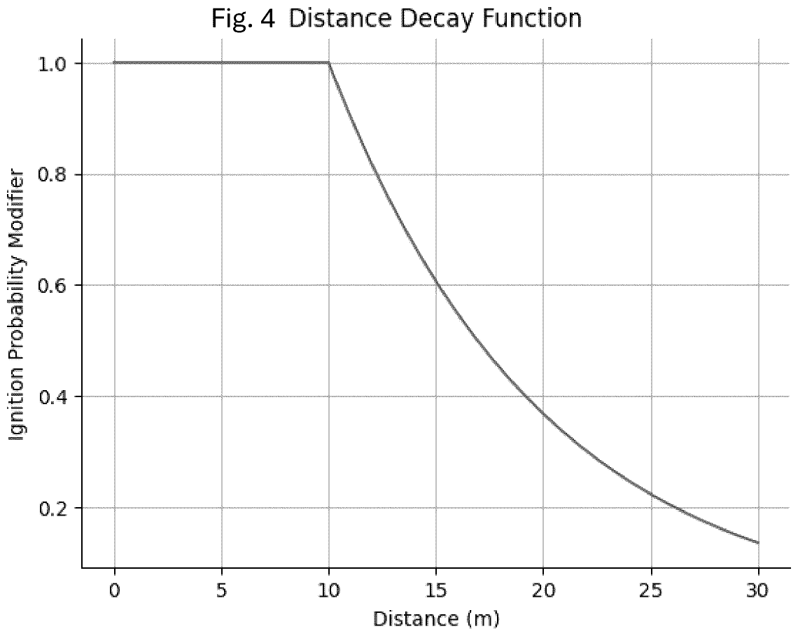

FIG. 4 is an example curve of a fire transmission probability modifier as a function of node separation distance, used to represent the decay of radiant heating.

### 2.5 Convective Heating and the Role of Wind Alignment

In addition to radiative heating, convective heating plays a significant role in fire transmission between structures. Convective heating occurs when wind carries hot gases from the burning source structure to an unignited target structure. The effectiveness of convective heating depends on the wind direction relative to the bearing between the two structures.

The convective heating contribution to fire transmission is modeled using the wind bearing effect, which modifies the transmission probability based on the angle between the wind direction and the bearing between the source and target nodes.

Formally, let represent the bearing between structure (source node) and structure (target node). Let represent the wind direction. The convective heating effect on the transmission probability is represented by accounting for the alignment of the wind with the bearing between the two nodes.

where:
is the bearing between structure and structure,
is the prevailing wind direction used for the fire pathways simulation.

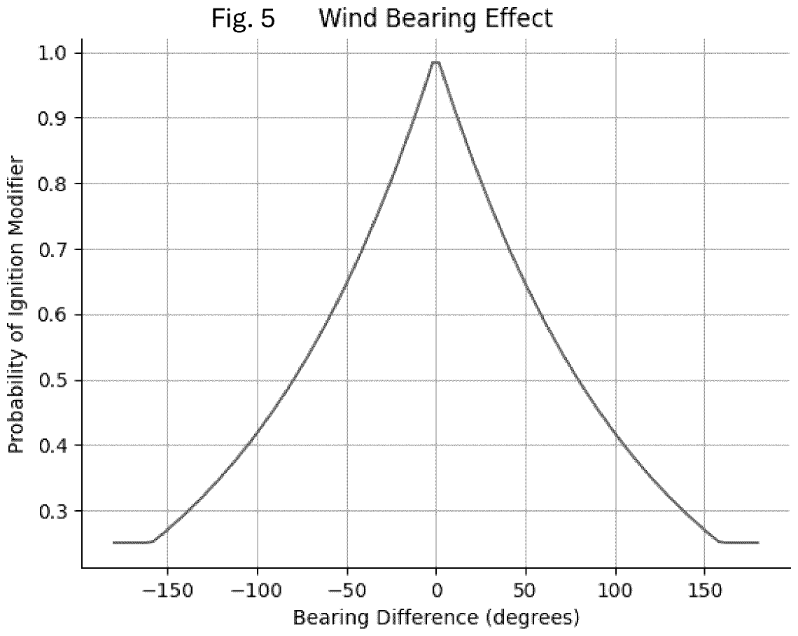

FIG. 5 shows wind direction effect on fire transmission probability as a function of the alignment (in degrees) between nodes and the prevailing wind direction.

In some embodiments, the model may also include the slope and alignment of wind and slope between the source and target nodes to improve the resolution of convective heating in fire spread.

### 2.6 Transmission Probability

Together, the time-dependent fire intensity at source node and the wind and distance effects describe the likelihood of a sufficient heating flux extending from to.

That joint probability can be defined mathematically as:

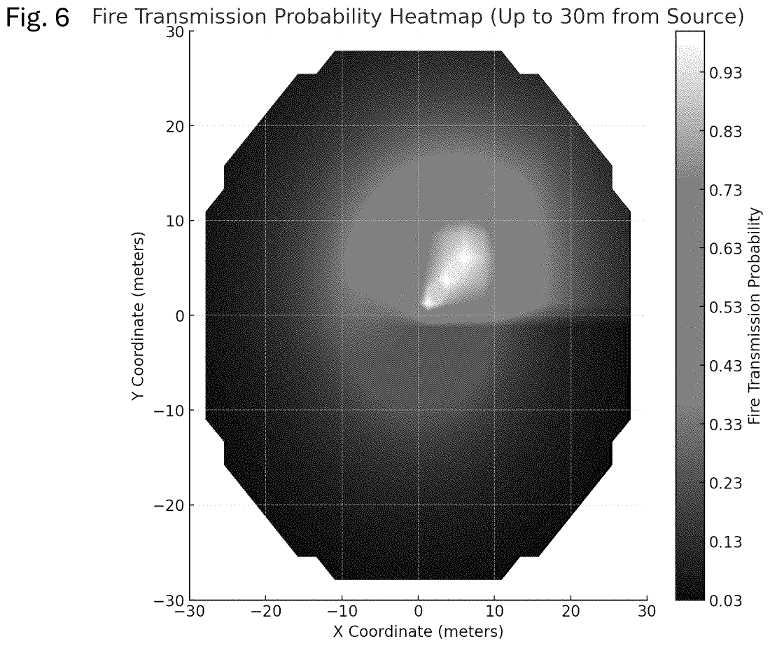

FIG. 6 shows composite probability of fire transmission incorporating both distance decay (radiative heating) and wind alignment (convective heat).

In the example of FIG. 6, the wind is modeled as coming from the bottom left corner (southwest).

### 2.7 Vulnerability and Structure Receptivity

All structures (regardless of size and material) are modeled as burning with the same intensity and with the same transmissive properties. However, the conditions at the target node (i.e., the structure receiving potential fire transmission) significantly affect the likelihood of fire transmission to those nodes, particularly when the transmission flux is
Home Hardening Factor: represents the structural features of the building that make it more resistant to ignition. Homes with fire-resistant materials, sealed vents, and other fireproofing measures have lower probabilities of catching fire.
Defensible Space Factor: The quantifies the clearance and removal of combustible materials around the structure.
Firefighter Presence: The presence of a firefighter at the target node is denoted by, where if a firefighter is actively defending the structure and otherwise. Firefighters significantly reduce the likelihood of ignition by mitigating fire spread through suppression techniques.
Distance: Even hardened homes and those with firefighters positioned at them are likely to ignite if they are very close to other structures. Distance indicates the distance to the neighboring structure along edge.

We define a weighted probability modifier based on these node-level conditions as follows:

$${S}_{target} ( hh , ds , ff , {d}_{ij} ) = \{ \begin{matrix}1 & if {d}_{ij} < 7 \\ \frac{2 \cdot hh + 1 \cdot ds + 1 \cdot ff}{4} & if {d}_{ij} \geq 7\end{matrix}$$

Where:
a. represents the home hardening factor,
b. represents the defensible space factor,
c. represents the presence of firefighter activity,
d. is the distance between the source and target nodes.

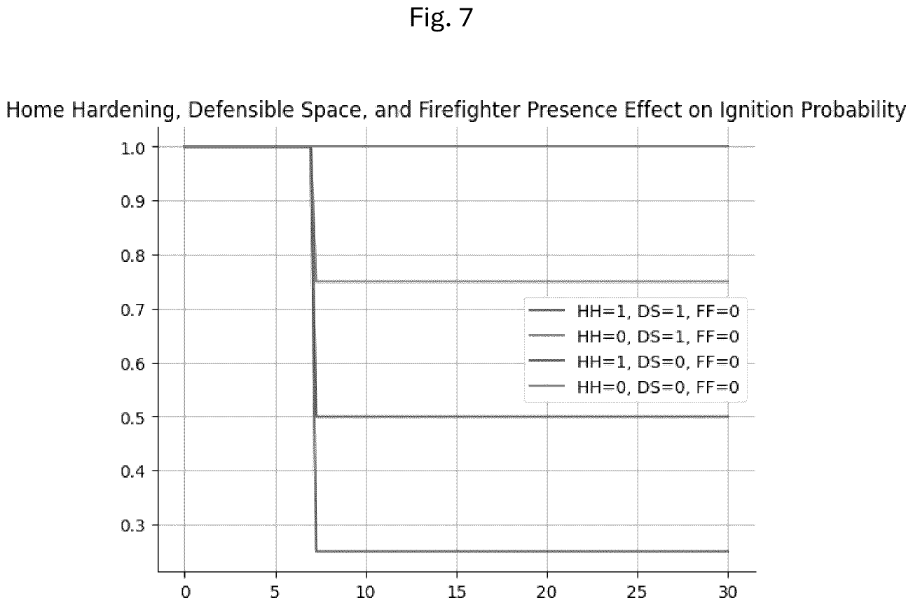

FIG. 7 is an example of home hardening, defensible space, and firefighter presence effect on ignition probability as a function of source to target node distance.

### 2.8 Composite Transmission Probability

The composite probability of transmission between nodes and is therefore the product of the fire intensity at the source node, the potential for radiant and convective heat transport between an, and the home hardening, defensible space, and firefighter presence characteristics of.

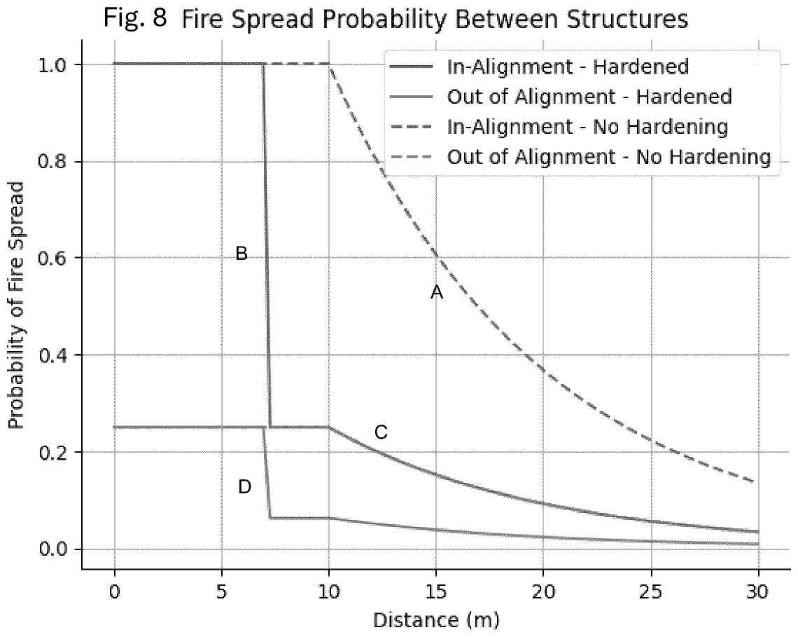

FIG. 8 shows an example of how these characteristics work together to facilitate fire spread between building nodes.

In particular, this figure shows fire spread probability for four different edges. (dashed line A—an unhardened structure where the edge aligns with the wind, solid line B—a hardened structure where the edge aligns with the wind, line C—an unhardened structure where the edge runs is in opposition to the prevailing winds (bearing delta=180 degrees), and solid line D—a hardened structure where the edge runs in opposition to the prevailing wind.

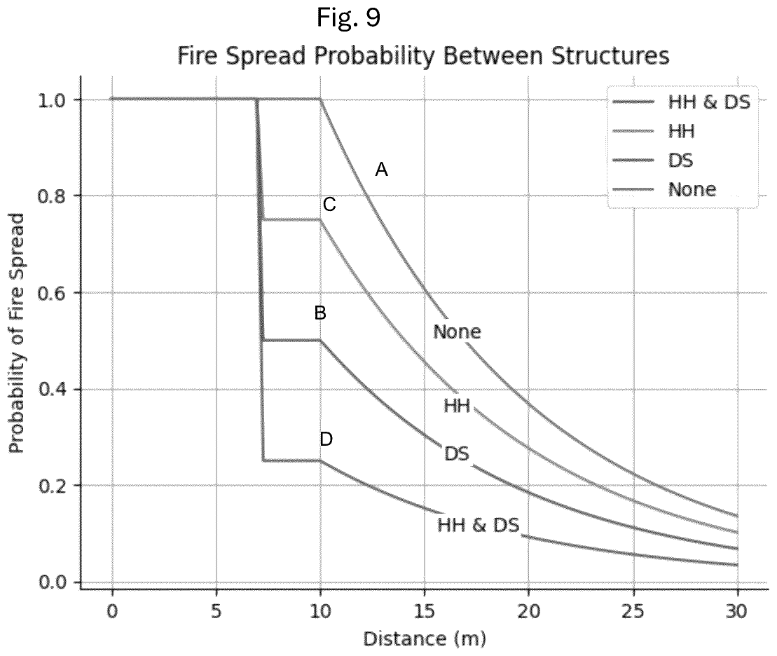

FIG. 9 shows modeled fire spread probability between four different edges.

Here the edges include line A—target structure has no hardening characteristics, line B—target structure has defensible space but no home hardening, line C—target structure has home hardening but no defensible space, and line D—target structure has both home hardening and defensible space characteristics.

### 2.10 Ember Spread (Transport and Deposition) (Step 216)

In an example model 126, ignited structures can produce embers that will propagate fire downwind through the prevailing wind field and, if deposited adjacent to structures, can ignite those structures.

### Ember Launch Probability

The probability of ember launch is primarily determined by the “fire intensity” at the burning source node. As the fire matures and reaches its “peak intensity”, the probability of launching embers increases. Subsequently, as the fire intensity decreases, the probability of ember launch decreases proportionally.

Let I(t) represent the fire intensity at time t at the source node. The relationship between fire intensity and ember launch probability is modeled as a direct proportional relationship. When the fire intensity is high, the likelihood of launching embers is greater, and as the fire burns out, this likelihood decreases. The “probability of ember launch”, denoted (P_{launch}(t), is proportional to the fire intensity and can be expressed as:
where: I(t) is the fire intensity at time t, and k is a constant of proportionality that determines the rate of ember launch as a function of intensity.

### Ember Trajectory and Deposition

Once launched, ember flight dynamics are governed by wind speed and direction. An ensemble of embers will be launched from each ignited building. Random adjustments to wind speed and wind are applied to the prevailing conditions. Simulated deposition locations are then checked against the building footprints to determine whether an ignition should be triggered.

Given:
a: Number of ember trajectories simulated.
b: Starting coordinates of the ember in meters.
c: Wind speed in meters per second.
d: Wind direction in degrees
e: Maximum duration of ember travel in seconds.
f: Theoretical maximum distance an ember can travel.
g: Relative fire intensity of the source structure

The actual number of simulated trajectories to calculate is dependent on the relative fire intensity of the structure.

Similarly, the maximum possible distance is scaled so that structures burning at peak intensity have the greatest potential for long-distance ember transport.

Then, the simulated trajectories are calculated using

Per-trajectory distances are then scaled against the maximum possible distance

where:

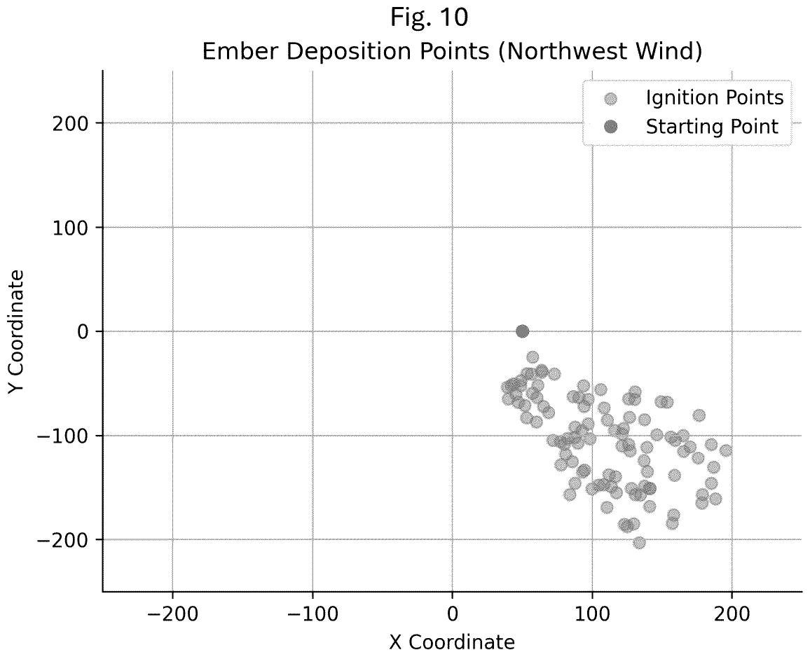

FIG. 10 is an example of a resulting simulated ember deposition from a burning structure node for a given wind direction and built environment model.

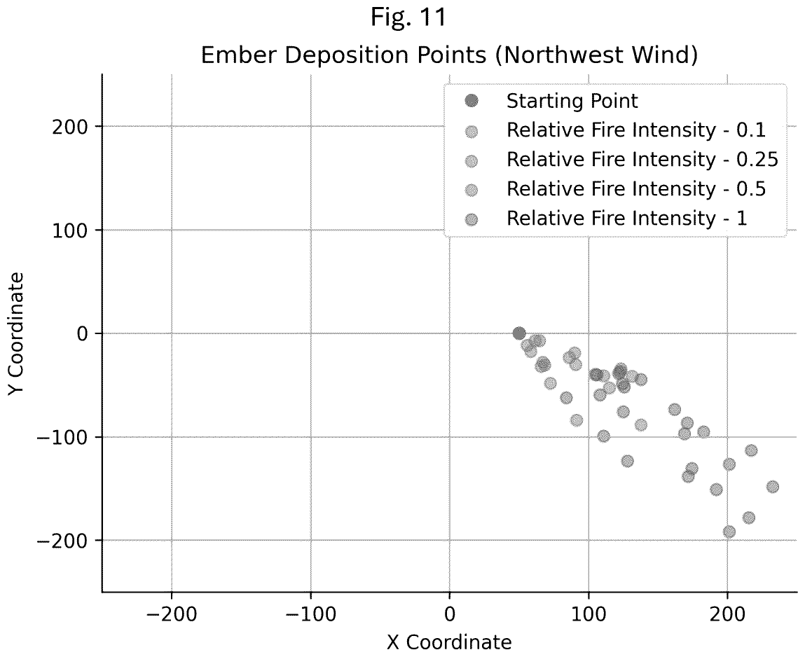

FIG. 11 is an example simulation result showing ember deposition at varying levels of relative fire intensity for the same built environment.

### Ember-Based Ignition

Once an ember is deposited, it has the potential to ignite adjacent structures (step 218 of FIG. 2). Whether an adjacent structure ignites depends on the location of ember deposition relative to the structure and the characteristics of the structure itself. The probability of ignition is determined by a combination of distance from the ember deposition point and several modifying factors, including defensible space, home hardening, and firefighter presence at the adjacent structure.

### Base Probability of Ignition

The base probability of ignition is primarily a function of the distance between the ember deposition point and the structure. The relationship between distance and ignition probability may follow a linear decay model, for which in one example:
a. At a distance of 0 meters from the structure, the base probability of ignition is maximum.
b. As the distance increases, the base probability of ignition decays linearly, reaching zero at a distance of 5 meters.
c. Embers deposited beyond 5 meters cannot ignite the structure, meaning the base probability is effectively zero.

This base probability can be expressed as:

where:
is the distance between the ember deposition point and the structure,
is the base probability of ignition.

### Modifying the Base Probability

The base probability of ignition may be further adjusted in step 218 by the characteristics of the adjacent structure. These factors either reduce or completely nullify the ignition probability:

Where:
represents the home hardening level (on a scale of 0 to 1),
represents the defensible space level (on a scale of 0 to 1),
is the reduction factor applied to the base probability.

The adjusted probability of ignition for a structure considering these protective factors is given by:

If a firefighter is present at the structure, the probability of ignition is reduced to zero, reflecting the suppression efforts provided by the firefighter. In this case, the ignition probability becomes:

The overall probability that an ember deposition results in the ignition of an adjacent structure is a function of both the distance and the modifying factors. Finally, a binomial draw with one trial is performed to determine if ignition occurs. The ignition is therefore defined probabilistically as:

### Ambient Ember Deposition and Ignition

Step 218 may also consider that embers can be generated by “wildland” fuels (non-structure fuels). At a background rate of alpha, embers are generated from nodes along the fire initial fire pathway and transported according to the equations given above. When deposited, they can ignite the structure as calculated above.

### 3.0 Fire Propagation and Simulation

Using a simulation loop, fire spread is propagated through the built environment, terminating when no nodes have sufficient fire intensity to ignite their surrounding nodes.

To initialize the simulation, fire pathways are used to calculate the nodes initially affected by vegetation fire. These nodes are ignited probabilistically depending on their home hardening and defensible space characteristics.

Subsequently, a simulation loop is used to propagate the fire through heat-transfer-based ignition and ember deposition.

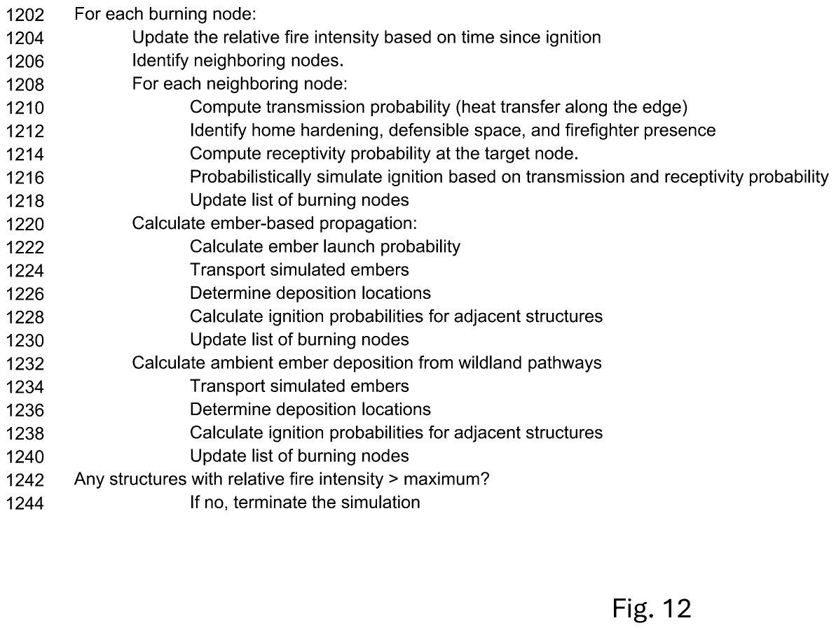

FIG. 12 illustrates each iteration of a simulation loop, where the following steps are performed (reference numbers in parenthesis correspond to steps illustrated in the figure):
a. For each burning node (1202):
b. Update (1204) the relative fire intensity based on time since ignition
c. Identify (1206) neighboring nodes.
d. For each neighboring node (1208):
   i. Compute (1210) transmission probability (heat transfer along the edge)
   ii. Identify (1212) home hardening, defensible space, and firefighter presence characteristics and (1214) compute receptivity probability at the target node.
   iii. Probabilistically simulate (1216) ignition based on transmission and receptivity probability
   iv. Update (1218) list of burning nodes
e. Calculate (1220) ember-based propagation. This may include:
   i. Calculate (1222) ember launch probability
   ii. Transport (1224) simulated embers
   iii. Determine (1226) deposition locations
   iv. Calculate (1228) ignition probabilities for adjacent structures
   v. Update (1230) list of burning nodes
f. Calculate (1232) ambient ember deposition from wildland pathways
   i. Transport (1234) simulated embers
   ii. Determine (1236) deposition locations
   iii. Calculate (1238) ignition probabilities for adjacent structures
   iv. Update (1240) list of burning nodes

After each burning node is processed, then
a. Check (1242) whether any structures have a relative fire intensity greater than 20% of the maximum. If no (1244), terminate the simulation loop.

### 4.0 Example Applications

The directed-graph fire spread models 126 lend themselves to a number of renderings and treatment plan evaluation applications.

In one example, synthetic data is used to review the spatial relationships between nodes.

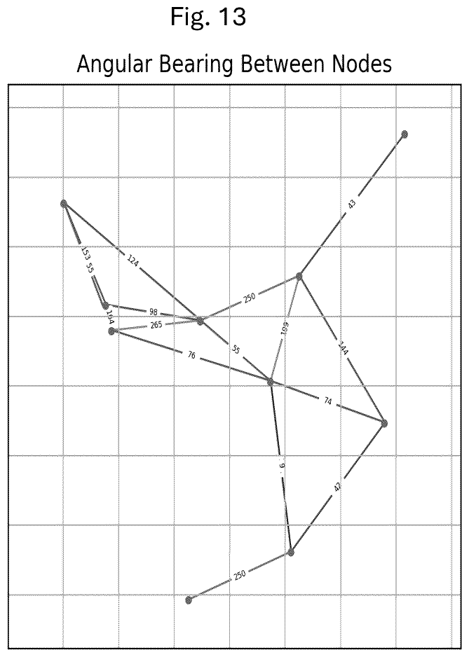

FIG. 13 is a graph of angular bearings between nodes for an example built environment. Using this angular bearing data, one can determine the weighting effect for convective heat transfer between each node pair.

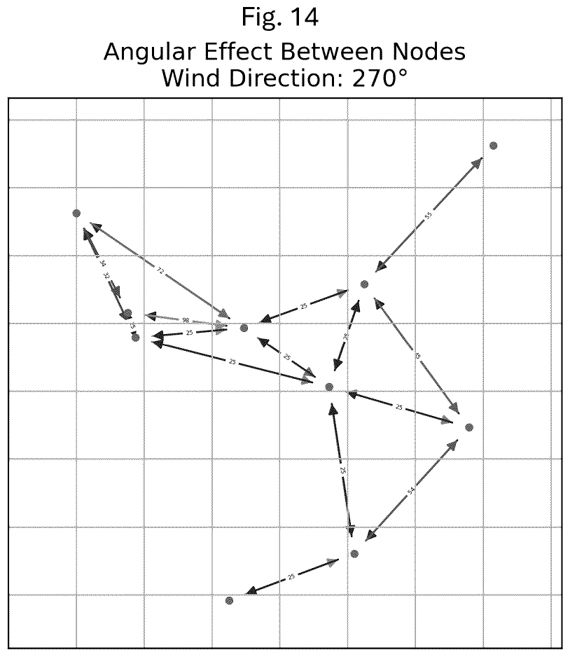

FIG. 14 is a resulting wind direction effect assuming a 270-degree (west) wind for nodes in the synthetic graph. It is seen that the wind effect will change depending on the wind direction.

Subsequently, the angular bearing and spatial distance between each pair of nodes can be manipulated to understand how those may further control spread. In one example, nodes are only connected with an edge if they are less than a certain predetermined distance, such as 30 m, from one another.

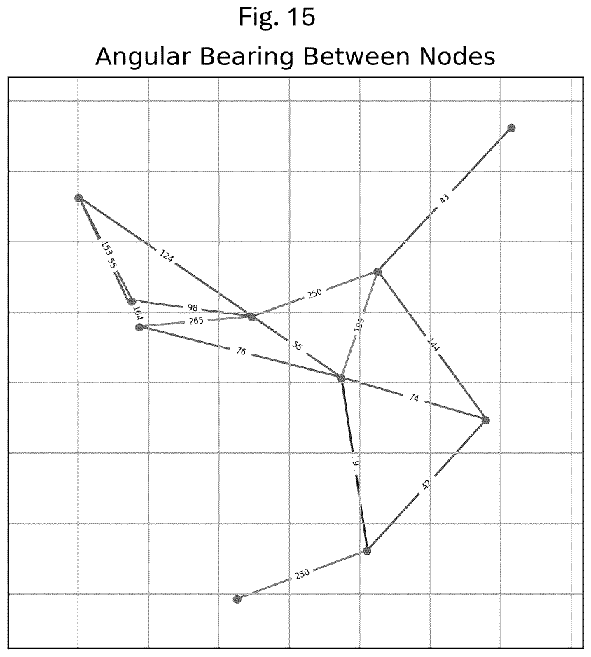

FIG. 15 is an example of the resulting angular bearing in degrees between node pairs with a 30 m spread constraint.

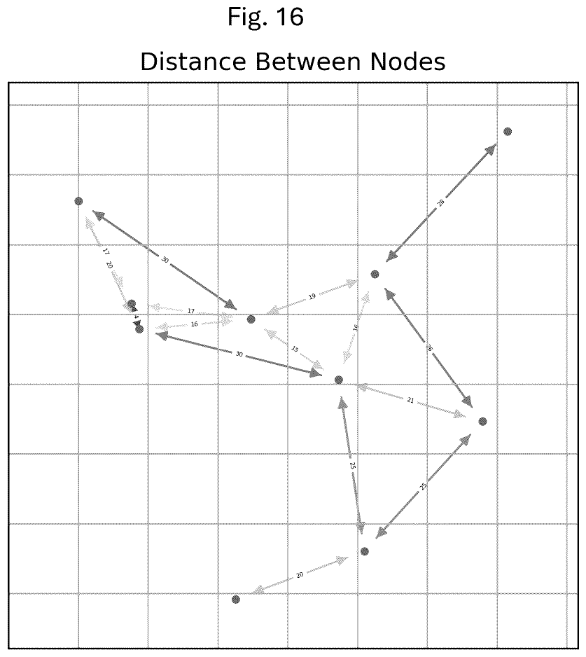

FIG. 16 shows angular distance in meters between each pair of nodes in the example built environment.

Radiant heat can also be modeled as decaying exponentially with distance from the radiation source.

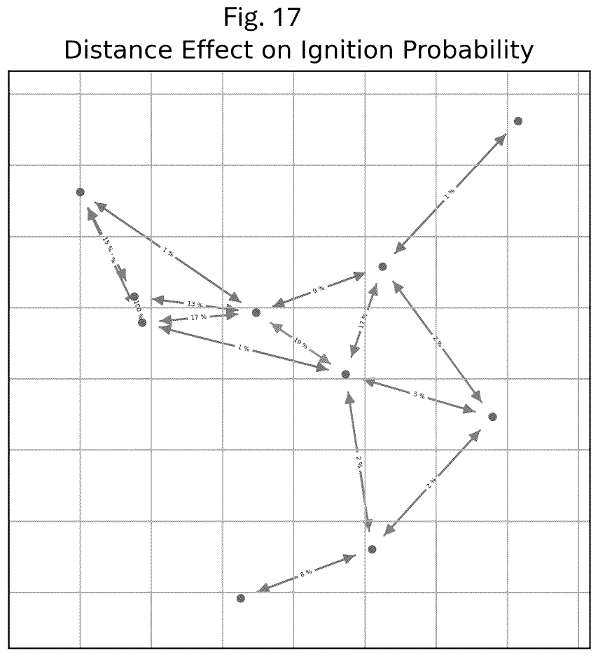

FIG. 17 is a graph of the probability of ignition modulated according to that distance effect, representing capacity for radiant heat transfer to transmit fire from one building to another.

Subsequently, the probabilities shown in FIG. 17 and those in FIG. 14 to produce a composite probability of direct fire spread between each pair of nodes. The nodes with high probabilities in this metric are those that are in alignment with the wind and also located close to another node.

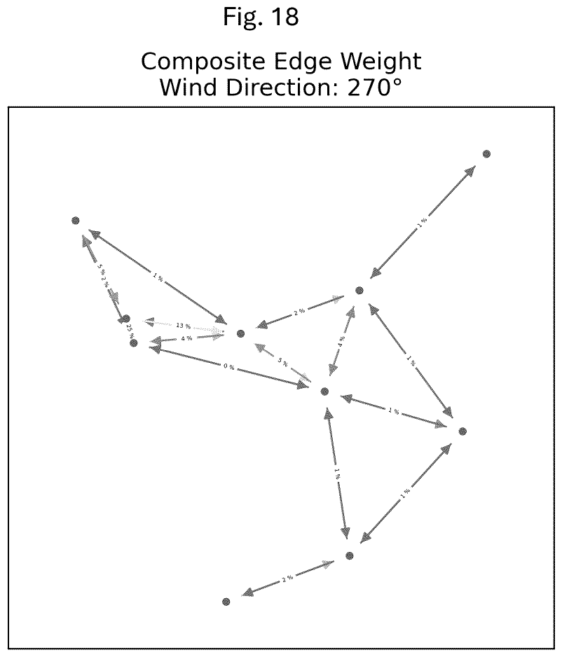

FIG. 18 illustrates an example of the composite fire transmission probabilities for a west wind.

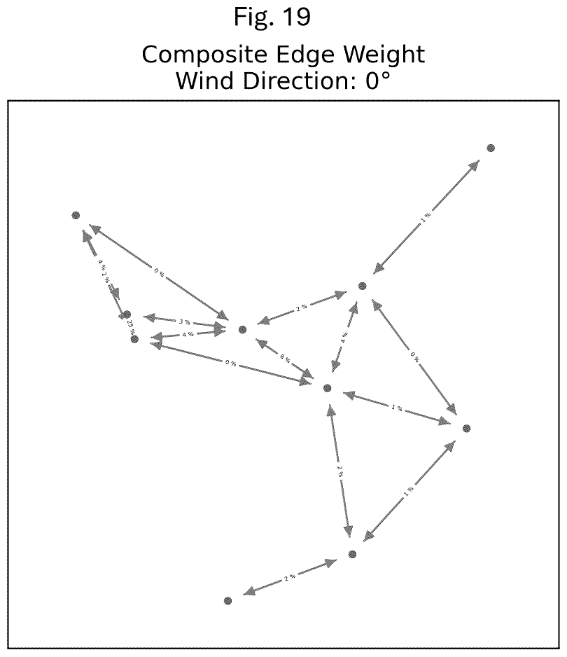

FIG. 19 shows example composite fire transmission probabilities for a north wind.

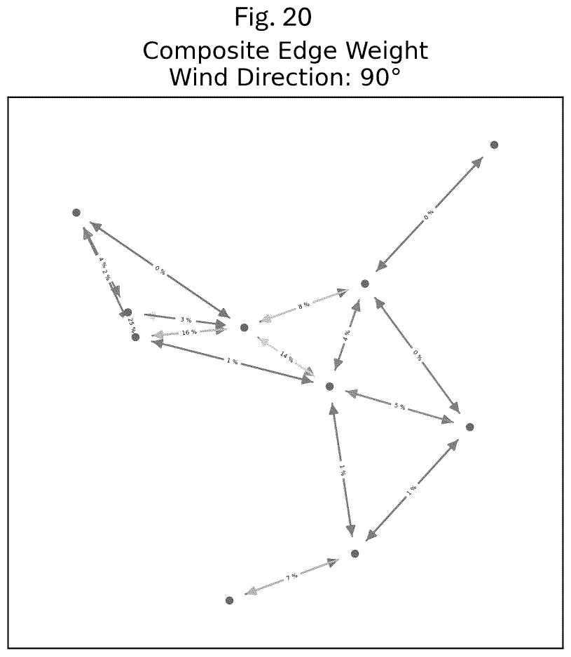

FIG. 20 shows example composite fire transmission probabilities for an east wind.

We can use the models to also calculate a sequence of fire ignition from an initially-ignited node.

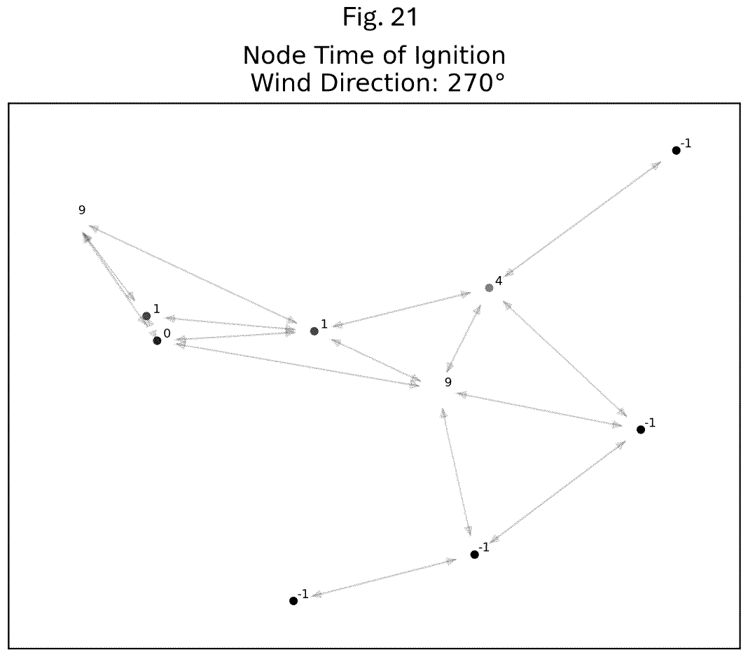

FIG. 21 shows an example transmission sequence (without embers) through the synthetic graph for a west wind. Node labels indicate the relative timing of ignition; nodes labeled −1 do not ignite during the simulation.

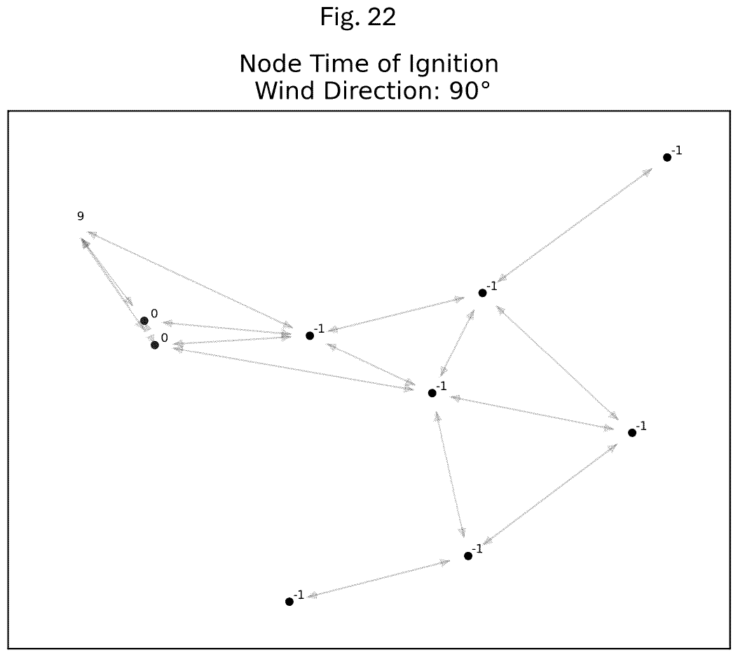

FIG. 22 shows an example sequence of ignitions in the synthetic graph for an east wind direction.

We can subsequently construct a model for a real built environment.

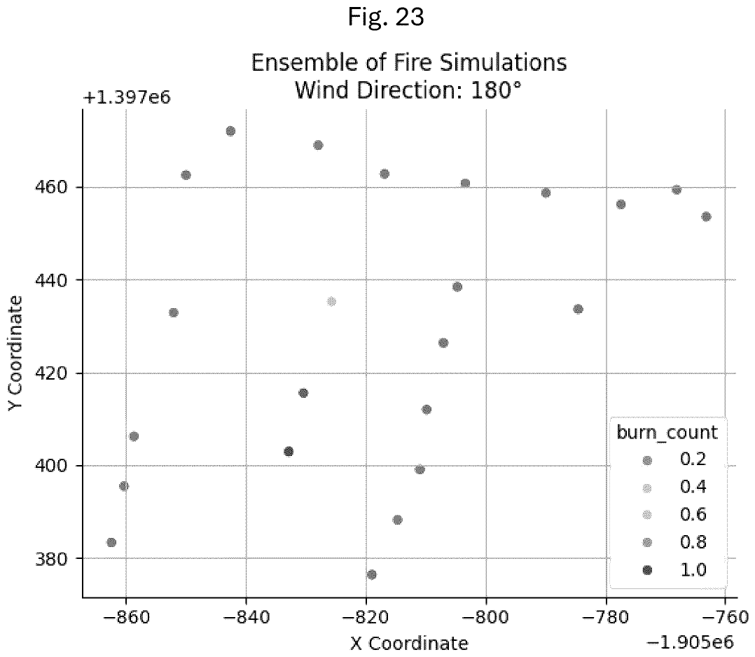

FIG. 23 shows the probability of ignition for each structure over an ensemble of 10,000 different simulations under a south wind, excluding embers.

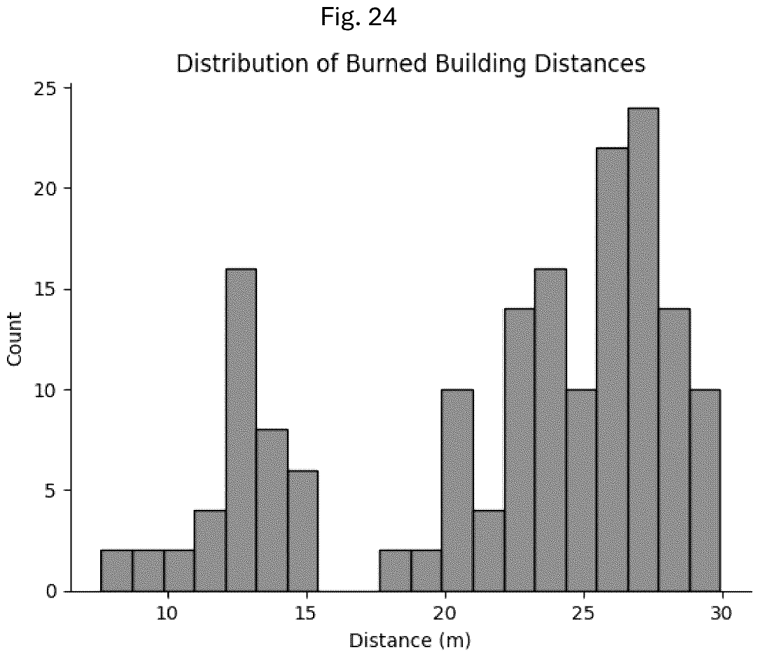

FIG. 24 shows the node-to-node distance of structures that ignited at least once during the simulation of FIG. 23.

Ember dispersal can also be modelled.

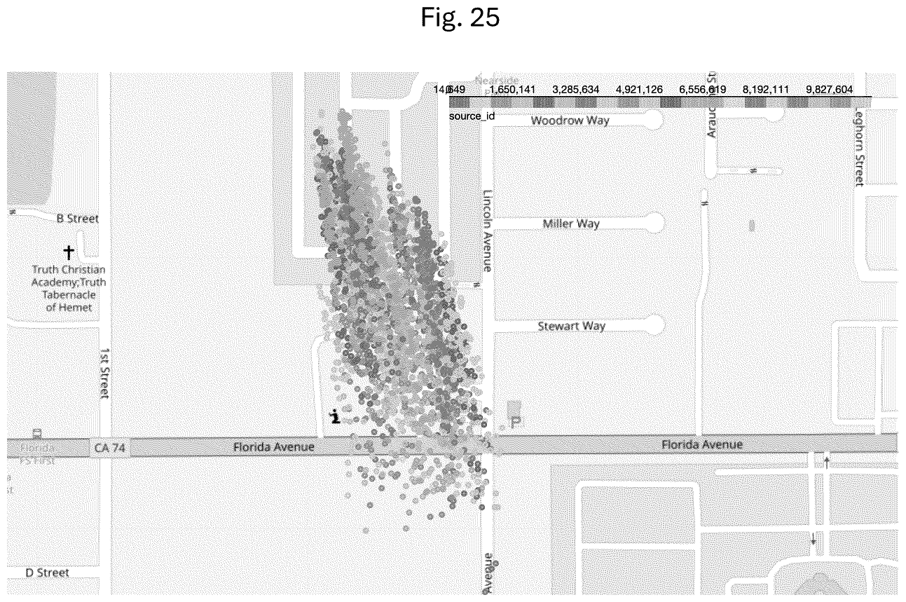

FIG. 25 is an plot of ember trajectories originating from different source nodes under a north wind scenario. It illustrates simulated ember deposition, shaded (or colored) by an identifier (ID) for each source node.

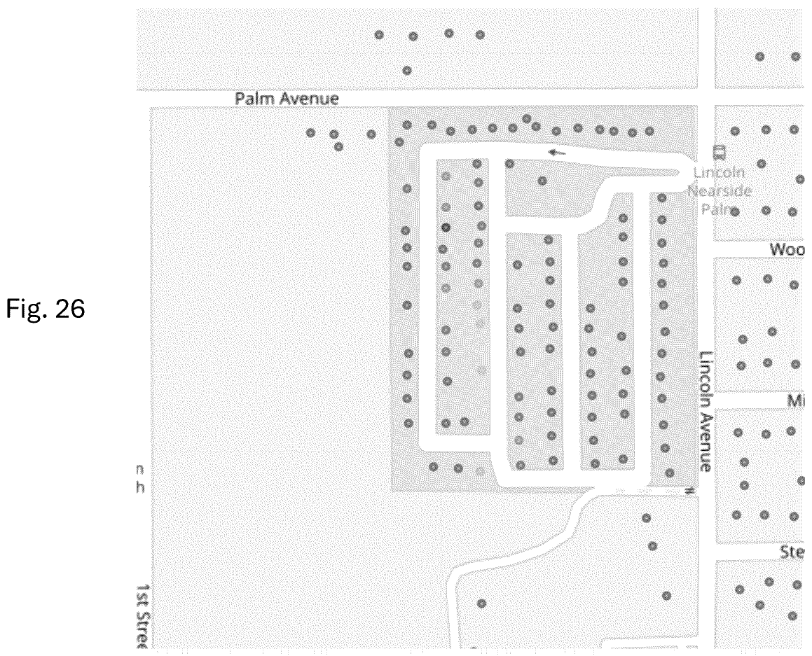

FIG. 26 illustrates burn probability for a neighborhood under a north wind incorporating both heat-based fire transmission and ember transport and deposition.

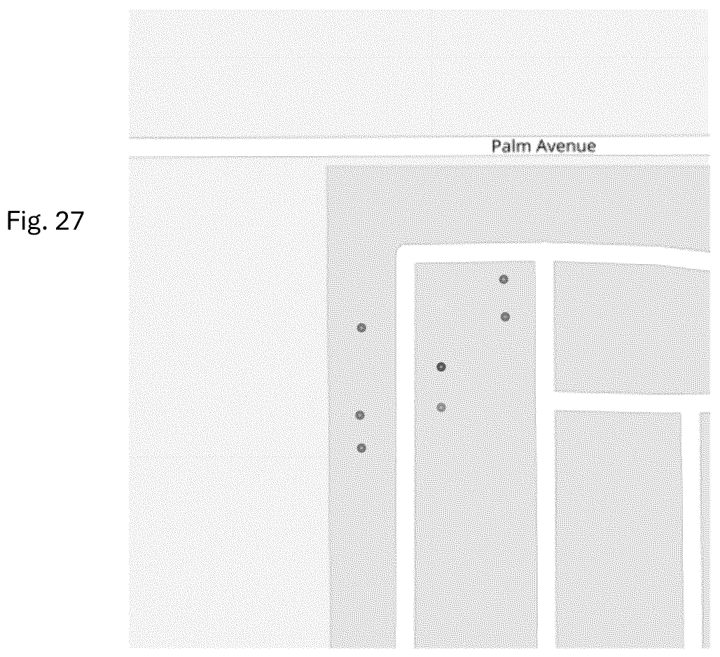

FIG. 27 illustrates burn probability for the same neighborhood under the same wind events, but where each structure has been at least partially hardened to resist ember-based ignitions.

### 5.0 Further Embodiments of the Fire Model

### 5.1 Overview

As now understood, directed-graph 120 based models 126 may be used to simulate fire spread through vegetated and built environments, incorporating radiant and convective heat, embers, and fire from fire front spread. The model is designed to be flexible, operational, and fast. The primary objectives of the model are to create a simplified and operationally useful tool for community wildfire risk assessment and mitigation prioritization.

The fire spread model 126 is graph-based 120. Fire spreads from fuel sources (nodes) along fire pathways (edges).

Basic principles of the model may include:
a. heat-transfer relationships between any two nodes are simple (well-understood thermodynamic rules), but,
b. complex emergent patterns will arise when these simple rules are applied to heterogeneous landscapes with varying structural density, fuel types, topography, weather, land uses, roads, etc,
c. therefore, not all mitigation activities have the same benefit.

Fire spread is time-based. The simulation is completed over a series of timesteps. At each timestep, fire propagates from currently ignited nodes to downstream unignited nodes.

The number of timesteps is up to the model user.

The nodes that ignite at the beginning of the simulation are specified by the user as a point.

Each node is ignited by exactly one upstream fire source. Unlike other models that sum the contributions of heat sources, the XFM creates a simplified framework with a one-to-many relationship between ignitions. Each node can ignite many downstream nodes, but each downstream node is ignited by only one upstream node. This facilitates tracking ignition dependency chains and assigning ignition reasons. Combined with ensemble techniques (see below), the full distribution of potential ignition sources for a given node can be enumerated.

The simulation is stochastic. Ignition and fire spread are random variables characterized by statistical distributions.

At each timestep, an event may or may not occur, according to the conditions at each node/edge and a probability distribution.

Different simulation runs will have different outcomes.

It is often useful to run an ensemble of many simulations to ensure convergence to a stable assessment of ignition patterns.

The simulation uses physical equations expressed as probability distributions.

This provides the stochastic underpinnings of the simulation system and enables reasoning about the relative likelihood of fire transmission between any two nodes.

These probabilistic functions can be updated over time to integrate better physical science and improve the model.

### 5.2 Nodes

Nodes in the graph 120 represent fuel sources. Nodes can be one of two types:
Vegetation: The fuel is wildland or urban vegetation. Each vegetation node is assigned a fuel model using Landfire data, from which rate of spread and flame length are calculated. Vegetation nodes can produce surface fire spread and ember transport.
Structures: The fuel is a structure. Structure footprints are derived from the Microsoft Buildings Footprint (MBF) dataset. Once ignited, structures burn at a specified rate (they don't reach maximum heat release immediately). Once a critical threshold has been reached, ignited structures can ignite other nodes through radiant/convective heating, surface fire spread, and ember production.

Nodes can be mitigated.

Mitigation in vegetation is represented by changing fuel model. Fuel reduction changes fuel model in standard ways, based on likely treatment methods (e.g., high-load brush to low-load brush).

Post-mitigation fuel models have lower rates of spread

Post-mitigation fuel models have lower flame lengths (which usually translates into lower likelihood of torching and subsequent ember production).

Mitigation state changes (Fuel Model A→Fuel Model B mappings) are deterministic.

Mitigation on structures is represented by changing the receptivity of the node to different types of fire exposure and the rate of heat release. Receptivity will be addressed in more detail later in this document, but, in general, it represents the likelihood that a fire exposure will result in the ignition of the node. Mitigated structures also take longer to begin emitting large amounts of radiant and convective heat.

Mitigations are supplied by the model user as Polygons. Any nodes within the polygon are mitigated. The model assumes that no nodes are mitigated unless explicitly configured otherwise or are reflected as mitigated in Landfire or Fire Aside. This is appropriate for baseline model runs.

### 5.3 Fire Spread Mechanisms

Fire can spread in several ways. Fire spreads from a node that is already ignited to adjacent node(s) via edges. Edges track the state (rate, progress, and completion) of fire spread along that potential mechanism's pathway.

Vegetation-to-Vegetation Surface Fire Spread (VF): This mechanism of fire spread represents the tendency of fire to spread between adjacent vegetation nodes. The rate of fire spread between two vegetation nodes is proportional to the rate of spread at the two nodes. The simulation system tracks the progress across an edge; the rate of travel at each timestep is a distance-interpolated mean of the two rates of spread (i.e., using the current completion, the model weights towards the ROS of the nearer node). By default, when two vegetation nodes are adjacent, the receptivity of the adjacent node is nearly 100%—fire spread from the ignited to the unignited node is almost guaranteed, given sufficient time (N.B.: vegetation-to-vegetation receptivity rate is a parameter and can be controlled by the model developer).

Vegetation-Sourced Embers (VSE): Vegetation can produce embers. There are two models of vegetation ember transport in the system:

Moderate-Range Transport from Timber: Embers are launched from the tree canopy. This occurs when (a) canopy fuels are present, (b) ladder fuels are present and (c) flame lengths are sufficient to cause torching. Ember deposition decays exponentially with distance; ember transport in excess of 1000 m is possible. Ember transport distance is dependent on (a) wind speed and (b) topographic position. Long distance ember transport is much less likely than short distance transport. (See, for example Peterson, et al. “Characterizing firebrands and their kinematics during lofting”, Physics of Fluids 36, 106611 (2024) https://doi.org/10.1063/5.0227024

Numerous embers are simulated for each potential source at each timestep.

Deposition locations are simulated for each simulated ember at each timestep.

If an ember lands at/near an unignited downstream node, that node can be ignited.

Downstream node ignition probability depends on that node's receptivity to embers.

Consequences of downstream node ignition depends upon the node's edge continuity.

If an ember lands at/near an ignited node, nothing happens.

Ember production rate (embers/minute) depends on fuel type. Timber fuels have greater ember production rates and more distant ember distribution than fine fuels. Ember production also depends on the time since ignition;

Radiant and Convective Heating (RCH): A structure node produces heat upon reaching the free burning stage of combustion. The rate of heat release from the burning structure is dependent on the time since ignition. Radiant heat is emitted in all directions, regardless of wind and slope factors. Convective heat is entrained in fluid plumes and aligns with wind and slope. This mechanism of heat transfer is sometimes called “structure-to-structure”.

A probabilistic model evaluates the distance, wind, slope, and heat production at the source node and determines the probability of ignition for each adjacent node. Radiant and convective heating mechanisms do not require any fuel sources between nodes and extend across roads or other non-burnable features.

Given a structure emitting the maximum heat release rate:
a. Radiant heat-caused ignition of nodes (both structures and vegetation) within about 7.5 m is almost certain.
b. Radiant heat-caused ignitions of nodes up to about 30 m away are possible; however, the likelihood of ignition drops exponentially with distance. Ignitions at 30 m are exceedingly unlikely. The model does not consider radiant heat ignitions at distances greater than 30 m.

Structures with non-peak heat release rates (either before or after they reach peak), are less likely (within the probabilistic model) to ignite nearby nodes, because less total flux will reach the adjacent node. This relationship changes at each time step, as the heat release rate of the structure evolves over time. See details below.

Convective heating increases the likelihood of ignition for adjacent nodes when they are aligned with the wind and slope vectors. As with radiant heating, the likelihood of a convective heat-caused ignition is lower when the structure is not at the peak heat-release rate.

Structure-Vegetation-Structure/Vegetation-Structure/Structure-Vegetation Surface Fire Spread (SFS): In most cases, two adjacent structures will have combustible fuels between them (e.g., landscaping, combustible fencing, hedges).

### Vegetation-to-Vegetation Surface Fire Spread.

The model assumes that adjacent structure nodes are connected by an edge along which surface fire could propagate.

Once a structure ignites and reaches a heat release rate threshold, surface fire begins to travel along the edges to adjacent structures.

Unless otherwise specified, the model assumes moderate-load, dry-climate brush between the two structures. This fuel model produces moderate rates of spread and moderate flame lengths.

Rate of spread is adjusted for wind alignment.

This mechanism is usually significantly slower than RCH, which occurs very quickly after the source structure has reached peak heat release.

The likelihood of initiating SFS is dependent on mitigation status at the burning structure.

Mitigated nodes (with zone zero) are less likely to result in this form of fire spread.

The likelihood of ignition through SFS is dependent on mitigation status at the source and target structures. Mitigated structures are less susceptible to ignition from surface fire spread, as they have a non-combustible zone zero.

Structure-Sourced Embers (SSE): Ember transport from burning structures is similar to ember transport from timber vegetation. Embers deposition decays exponentially with distance from the burning structure. Moderate-to-long distance transport is anticipated due to large embers and high thermal mass. Ember production rate is dependent on the structure's area and intensity. Structure embers are only produced when a critical intensity threshold has been reached (pre-peak HRR fires do not produce embers).

### 5.4 Attributes of the Directed Graph 120

### Data Sources

a. Fuels: Landfire
b. Structures: Microsoft Building Footprints
c. Non-burnable land-uses: Open Street Map
d. Roads: Open Street Map

### Configuring Roads and Non-Burnable Surfaces

Roads and non-burnable surfaces change the ability for fire to spread through some mechanisms.
a. Landfire Non-Burnable: Nodes where landfire indicates a non-burnable fuel type (water, urban land use, etc) are removed from the graph. They are not receptive to any fire spread mechanism, cannot ignite, and cannot transmit fire to new locations. Fire can spread over these features through either embers or direct flame at diagonal pixel corners.
b. Non-Burnable Land Uses: Areas mapped as a non-burnable land use in Open Street Map are modified to reflect their non-burnable nature. Polygons representing golf courses, orchards, vineyards, fields, parking lots, sports pitches, stadiums, fairgrounds, commercial districts, plant nurseries, cemeteries, (covered) reservoirs, tracks, rec areas, industrial districts, and airport runways are obtained from OSM. Nodes and edges within any of these polygons are removed.
c. Roads: The road network may be obtained from OpenStreetMap (https://www.openstreetmap.org). (In some embodiments, road width is not considered, but it could be). Because surface fuels are discontinuous, surface fire (SFS and VF) cannot travel across roads. SFS and VF edges that cross a road are removed and will not be considered during the simulation. Other fire spread mechanisms (SSE, VSE, and RCH) are unaffected—they can spread between nodes separated by a road.

### Configuring Wind Speed

In some embodiments, a tool such as Wind Ninja (available from the U.S. Department of Agriculture, Missoula Fire Science Laboratory, https://ninjastorm.firelab.org/windninja/ may be used to produce node-specific wind speed and direction. This is incorporated into ember transport modules.

Topographic Position Index (PTO) such as described in “Topographic Positon Index for QGIS”, Feb. 11, 2019 https://landscapearchaeology.org/2019/tpi/ is a method of terrain classification where the altitude of each data point is evaluated against its neighborhood. If a point is higher than its surroundings, the index will be positive, as for example on ridges and hilltops, while the figure will be negative for sunken features such as valleys. TPI may be used in the models 126 to evaluate relative topographic position (ridgetop, valley bottom) in ember transport modules. Nodes with high TPIs are likely to launch embers further than lower-TPI peers.

### 5.5 Example Outputs

### Per-Run Outputs

For each member in the ensemble, several files may be produced:

Node Export: A detailed file about the state of each node:
a. Ignited (yes/no)
b. Time of ignition. We can animate this file with the time property.
c. Reason for ignition
d. Source of ignition (upstream node id)
e. Rate of spread/flame length/torching
f. Wind speed and direction
g. Node type (structure, vegetation)
h. Downstream descendents:
   i. The number of downstream descendents is calculated by evaluating the number of nodes that include this node in its dependency chain.
i. Dependency tree: For the given run, dependency relationships as lines.
   1. Each line has a time property, indicating the time at which the edge was active

Node Analysis File
a. A summary file describing, for each node:
   i. Average ignition frequency/probability (times ignited/total runs)
   ii. Average time of ignition
b. # of times ignited by each fire spread mechanism

### Auxiliary Files:

i. Ember deposition: All ember transport and deposition data is available in google storage after the runs.

### 5.6 General Simulation Flow Alternatives

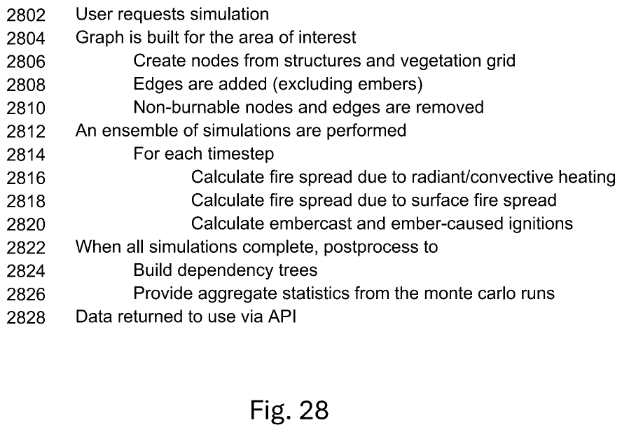

FIG. 28 is an example work flow for a fire spread simulation.

User requests (2802) a simulation.

Graph is built (2804) for an area of interest:
i. Nodes are created (2806) from structures and a regular vegetation grid
ii. Edges are added (2808) (excluding embers)
iii. Non-burnable nodes and edges are removed (2810).

An ensemble of simulations (2812) are performed:
a. For each timestep (2814):
   i. Calculate fire spread (2816) due to radiant/convective heating
   ii. Calculate fire spread (2818) due to surface fire spread
   iii. Calculate embercast and ember-caused ignitions (2820)
b. When all simulations are complete (2822), postprocess to:
   i. Build dependency trees (2824)
   ii. Provide aggregate statistics (2826) from the statistical (Monte Carlo) runs
   iii. Return data (2828) to user via API

### 5.7 Detailed Flow

The graph is typically configured once per study area. Multiple simulations typically use the same graph.

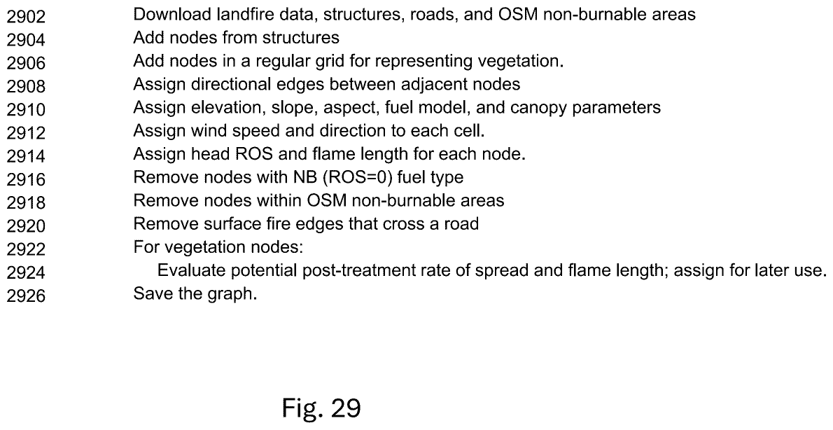

FIG. 29 is an example workflow for building a graph (steps 2804-2810 of FIG. 28).
a. Download (2902) landfire data, structures, roads, and OSM non-burnable areas
b. Add nodes (2904) from structures
c. Add nodes (2906) in a regular grid for representing vegetation. In one example, the resolution of the grid is 30 m.
d. Assign directional edges (2908) between adjacent nodes
e. RCH edges connect nodes within 30 m (2910);
   i. Surface fire edges (VF and SVS) connect nodes within 100 m; and
   ii. Ember edges are added dynamically in the simulation loop, not in the configuration step.
   iii. Assign elevation, slope, aspect, fuel model, and canopy parameters (2910) for each vegetation node.
f. Run WindNinja (2912) and assign wind speed and direction to each cell.
g. Run Rothermel calculations (2914) and assign head ROS and flame length for each node.
h. Remove nodes (2916) with NB (ROS=0) fuel type
i. Remove nodes (2918) within OSM non-burnable areas
j. Remove surface fire edges (2920) that cross a road
k. For vegetation nodes (2922), evaluate the potential post-treatment rate of spread and flame length and assign (2924) these variables to the node for later use.
l. Save the graph (2926) in a suitable format such as gpickle.

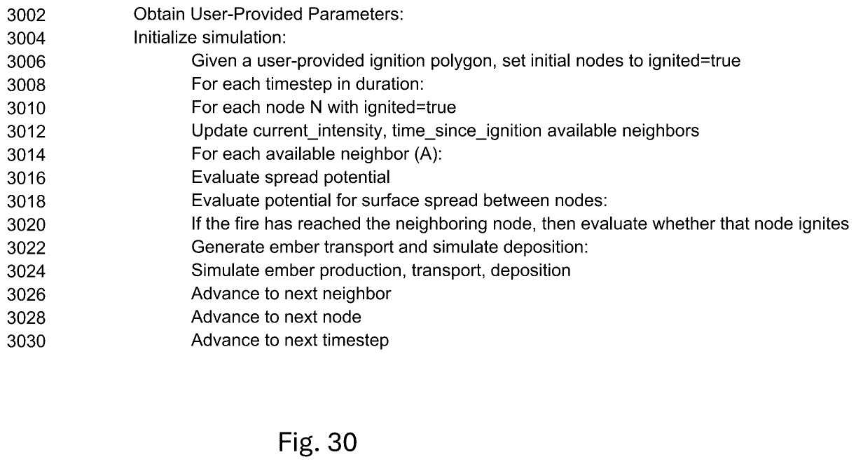

FIG. 30 is an example workflow for each simulation (steps 2812-2826 of FIG. 28).

For each simulation:
a. Obtain (3002) User-Provided Parameters such as
   i. Wind Speed (mph)
   ii. Wind Direction (degrees)
   iii. Initial ignition location (polygon)
   iv. Mitigation location(s) (polygon)
   v. Additional buildings (polygon)—for representing potential development scenarios
   vi. Duration (minutes)
   vii. Initialize simulation (3004):
   viii. Given a user-provided ignition polygon (3006), set initial nodes to ignited=true
   ix. For each timestep in the duration (3008):
   x. For each node N with ignited=true (3810)
      1. Update (3812) current_intensity (3812)
         i. time_since_ignition
         ii. available neighbors (connected nodes that are not yet ignited)
      2. For each available neighbor (A) (3014):
      3. Evaluate spread potential (3016) through radiant and convective heating
         a. Spread probability p depends on distance between nodes, wind speed, wind direction alignment, and current_intensity.
         b. The model treats ignition as a probability (weighted coin flip):
         i. If the coin lands “yes,” the neighbor ignites. Set ignited=true.
         ii. If it lands “no,” the fire does not spread there in that timestep.
         iii. Coin is weighted by p so more probable edges are more likely to cause ignition.
      4. Evaluate potential for surface spread (3018) between nodes:
         i. If an edge does not yet have surface spread, initialize surface spread (i.e., surface spread has begun to spread between N and A). Set edge completion=0.
         ii. Calculate current rate of spread by interpolating the rates of spread of N and A weighted by the current competition fraction.
         iii. Calculate adjusted rate of spread.
         iv. Elliptical model is used to evaluate heading vs. flanking vs. backing rates.
         v. Calculate the number of meters traveled in this timestep (N.B.: timesteps are usually 1 minute long). Update the total distance traveled along that edge.
         vi. Update edge completion to be the total distance traveled divided by the total length of the edge.
         1. If the fire has reached the neighboring node, then evaluate whether that node ignites:
         2. Ignition probability p is based on receptivity. Vegetation receptivity is ~1 (nearly certain). Structure receptivity depends on structure mitigations. Unmitigated structures (no zone zero, combustible attachments) have a high receptivity. Mitigated structures (non-combustible zone zero) have much lower receptivity because surface fire is not likely to result in direct flame contact between vegetation and structure.
         vii. The model treats ignition as a weighted coin flip:
         1. If the coin lands “yes,” the neighbor ignites. Set ignited=true.
         2. If it lands “no,” the fire does not spread there in that timestep.
         3. Coin is weighted by p so more probable edges are more likely to cause ignition.
   xi. Generate ember transport (3022) and simulate deposition:
   xii. Simulate ember production (3024) (dependent on fuel type and current intensity).
      1. This may include sub-steps such as
         i. Simulate ember transport
         ii. Exponential decay with distance, incorporating WindNinja wind speed/direction and topographic position index (in some implementations, the transport implicitly accounts for ember burnout, however it can also explicitly simulate ember burnout for improve resolution of longer-range ember transport).
         iii. Simulate ember deposition
         iv. Evaluate landing locations relative to nodes. If landing location is near a node, then evaluate node receptivity. Receptivity depends on node type (structure vs. vegetation) and mitigation state (mitigated vs. unmitigated). Ignition probability p is a function of receptivity.
         v. The model may treat ignition as a weighted coin flip:
         vi. If the coin lands “yes,” the neighbor ignites. Set ignited=true.
         vii. If it lands “no,” the fire does not spread there in that timestep.
         viii. Coin is weighted by p so more probable edges are more likely to cause ignition.
   xiii. Advance to next neighbor (3026)
   xiv. Advance to next code (3028)
   xv. Advance to next timestep (3030).

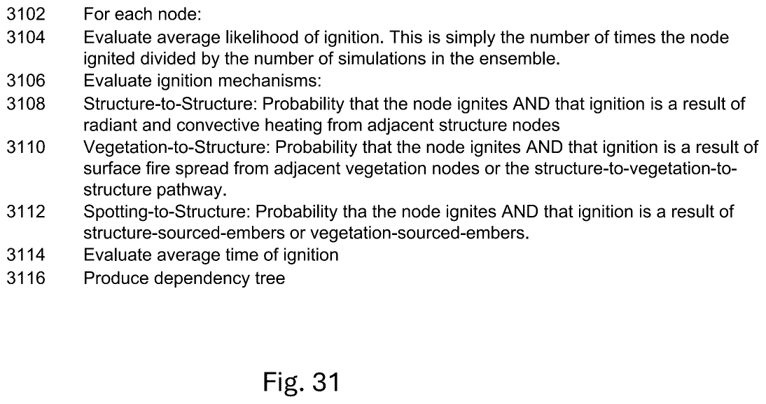

FIG. 31 is an example process flow for combining simulations.

For each node (3102):
a. Evaluate average likelihood of ignition (3104). This is simply the number of times the node ignited divided by the number of simulations in the ensemble.
b. Evaluate ignition mechanisms (3106):
c. Structure-to-Structure (3108): Probability that the node ignites AND that ignition is a result of radiant and convective heating from adjacent structure nodes
d. Vegetation-to-Structure (3110): Probability that the node ignites AND that ignition is a result of surface fire spread from adjacent vegetation nodes or the structure-to-vegetation-to-structure pathway.
e. Spotting-to-Structure (3112): Probability that the node ignites AND that ignition is a result of structure-sourced-embers or vegetation-sourced-embers.
f. Evaluate average time of ignition (3114)
g. Produce dependency tree (3116):
   Link ignitions into causal parent to descendent relationships. In some implementations, the dependency tree is a single-simulation artifact. It produces the results of a single simulation, rather than the joint results of the full ensemble. However the dependency tree can be a Markov chain-type model that shows transition probabilities between nodes, incorporating information from many simulations.

### 5.8 Structure Heat Release and Fire—Further Development

Structures don't burn immediately. Heat production evolves over time as the fire moves through the structure.

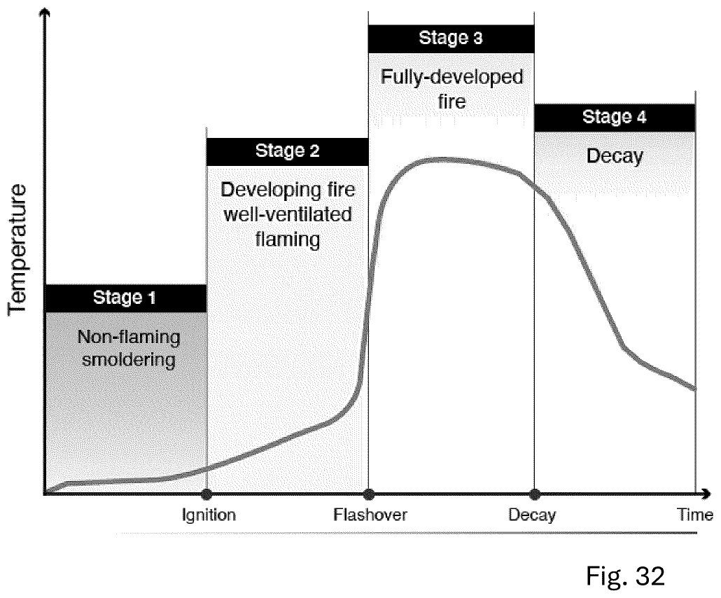

FIG. 32 is a Traditional Fire Development curve (from the NIST). Heat release matures at the fire grows, peaks for some period of time, then decays as the structure burns down.

The fire spread model 126 may use such a development curve to model fire intensity across time. For example, the model may use relative fire intensity as a function of maximum heat release rate.

The development model can follow a piecewise form:

$$I ( t ) = \{ \begin{matrix}0 , & t < ω , \\ \frac{\text{?} - 1}{{e}^{2} - 1} , & 0 \leq {t}^{′} < ρ , \\ 1 , & ρ \leq {t}^{′} < ρ + π , \\ \frac{ρ + π + δ - {t}^{′}}{δ} , & ρ + π \leq {t}^{′} < ρ + π + δ , \\ 0 , & {t}^{′} \geq ρ + π + δ .\end{matrix}$$

$$\text{?} \text{indicates text missing or illegible when filed}$$

Where:
a. ω is the latent incubation time
b. t′ is the number of minutes after ignition
c. ρ is the ramp time
d. π is the peak time
e. δ is the decay time

### Some Assumptions.

Ignition has a “latency time” during which no heat is emitted. This phase is usually short for unmitigated structures, but is included to represent the latent effects of ember deposition for mitigated structures.

Once ignited, fire growth proceeds exponentially for p minutes.

After p minutes, the fire emits the maximum heat release rate for π additional minutes

Finally, the fire begins to decay and heat release declines linearly for an additional b minutes

Mitigated structures and unmitigated structures have the same fire development model, but use different parameters:
a. Mitigated structures:
   i. Have a longer latency period, to reflect the role of embers and other latent ignition mechanisms
   ii. Have a longer ramp period to reflect the slower burning rate of fire resistant building materials
b. Unmitigated structures:
   i. Have a faster latency period—more vulnerabilities to exploit mean that latent ignitions are less likely than immediate ignitions
   ii. Have a faster ramp period—combustible materials develop more quickly
c. Both structure types have the same peak release rate period and decay period.

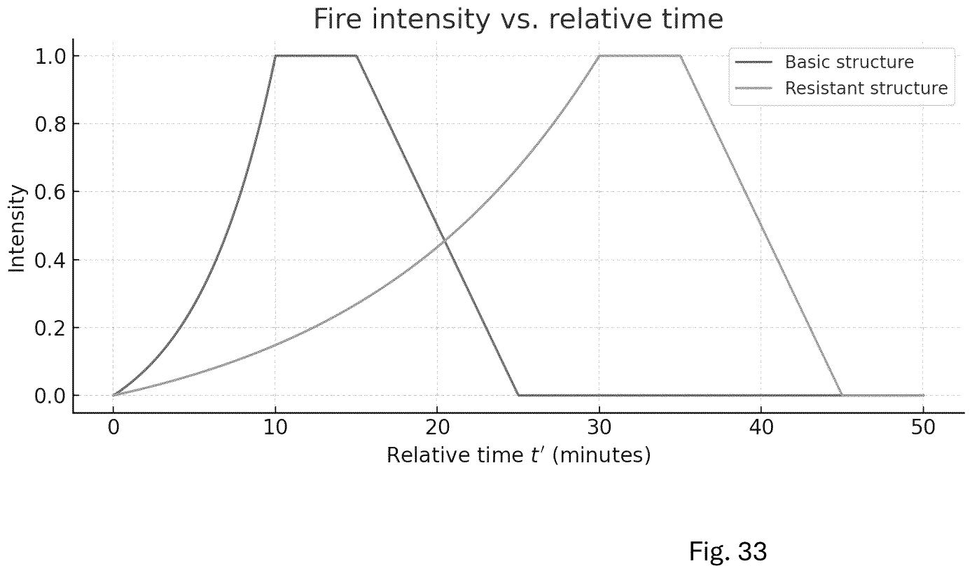

FIG. 33 shows fire development curves for mitigated (fire-resistant) and unmitigated (basic) structures.

### 5.9 Radiant and Convective Heating Module

In simple terms, to evaluate the potential for radiant and convective heat spread between two structure nodes, we define a probability function that incorporates:
a. The current intensity of the source structure,
b. The distance between the two structures
c. The alignment between the straight-line-bearing between the two structures and the prevailing wind vector
d. The mitigation conditions at the source and target structures

Short edges, in alignment with the wind, between unmitigated nodes are highly likely to ignite. Distant nodes and those perpendicular with or against the wind are unlikely to ignite. Close-together nodes may ignite regardless of mitigation status, if the distance is short enough.

Note, the XFM uses a probabilistic system based on simple probabilities; however, the underlying fundamentals are the same as those in other models, namely convective heat transport and radiant heat transport. The advantage of the XFM approach, is, that by converting to a probabilistic approach, rather than a deterministic physical approach, the between-node mathematics are easier to interpret and modify.

### Radiant Heat Module

Radiative heating is a key mechanism for fire spread between structure nodes. Received radiant heat decreases exponentially with distance, so structures farther apart are less likely to ignite due to radiative heat transfer. The model incorporates this effect via a distance decay model, where the probability of fire transmission declines exponentially with distance between the source and target structure. Structures that are closer than about 30 feet (centroid-to-centroid) receive the full value of the radiant heating, while structures further away receive only a portion of the heat.

Mathematically, we define the distance decay function for radiative heating as:

$${f}_{decay} ( {d}_{ij} ) = \{ \begin{matrix}1 & if {d}_{ij} < 7 \\ exp ( - 0.1 \cdot {d}_{ij} + 1 ) & if {d}_{ij} \geq 7\end{matrix}$$

Where is the distance between the node and node in meters.

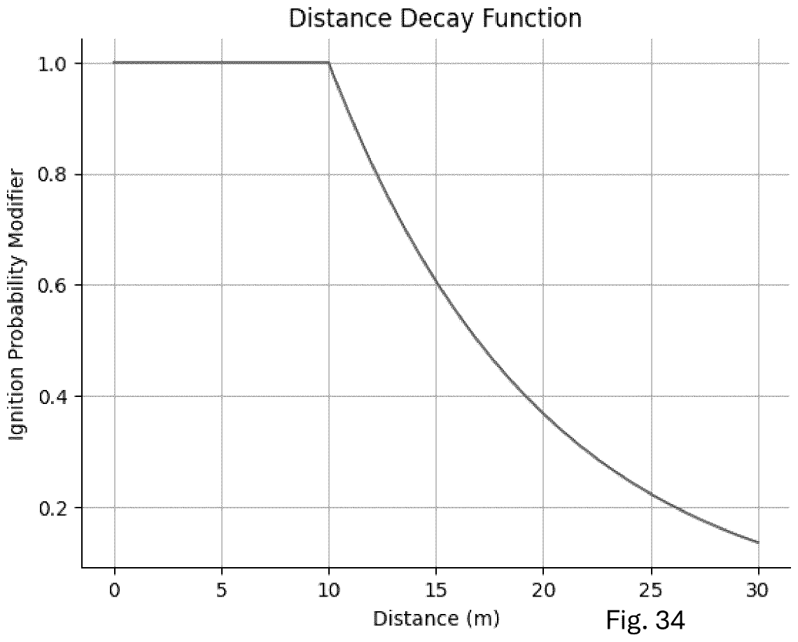

FIG. 34 shows radiant heat fire transmission parameter as a function of node separation distance.

### Convective Heat Module

In addition to radiative heating, convective heating plays a significant role in fire transmission between structures. A convective heat module may be part of simulation module 112. Convective heating occurs when wind carries hot gases from the burning source structure to an unignited target structure. The effectiveness of convective heating depends on the wind direction relative to the bearing between the two structures.

The convective heating contribution to fire transmission is modeled using the wind bearing effect, which modifies the transmission probability based on the angle between the wind direction and the bearing between the source and target nodes.

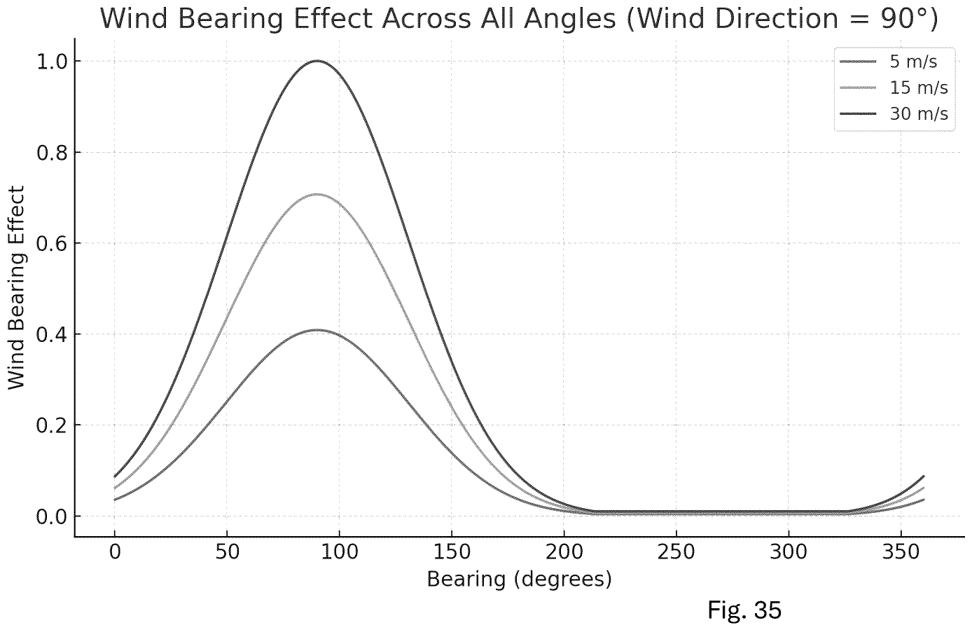

FIG. 35 shows Convective heat fire transmission parameter as a function of bearing. Assumes prevailing wind at 90 degrees.

### 5.10 Ember Transport Module

An ember transport module may be part of simulation module 112 and serves to simulate wind-driven ember travel. From a burning node, embers are produced, carried by the wind, and deposited downwind. Ember transport is stochastic—the ember transport module leverages random processed in several places to reflect likely—but unpredictable—patterns in ember dispersal.

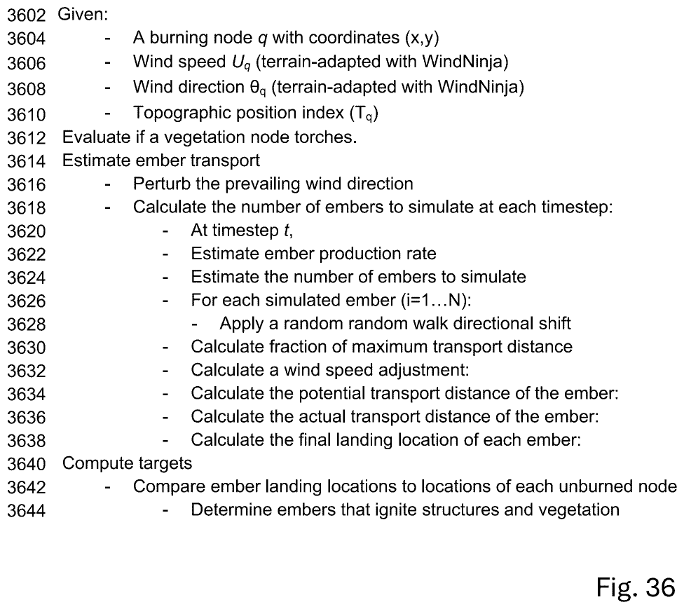

FIG. 36 is a workflow for an example ember transport module.

Given (3602) the following inputs:
a. A burning node q (3604) with coordinates (x,y)
b. Wind speed U_{q} (3606) (terrain-adapted with WindNinja)
c. Wind direction e_{q} (3608) (terrain-adapted with WindNinja)
d. Topographic position index (T_{q}) (3610)

For vegetation nodes:
a. Evaluate whether the node torches (3612).
   i. Torching if:
      1. Canopy cover >10%
      2. Flame length >base height*0.8

Estimate ember transport (3614):
a. Perturb the prevailing wind direction (3616) by a random constant.
b.

$$\tilde{θ} = ( θ + 𝒩 ( {μ}_{θ}^{deg} , {σ}_{θ}^{deg} ) )$$

c. μ and σ are noise constants.
d. Calculate the number of embers (3618) to simulate at each timestep:
   i. At timestep t, (3620)
   ii. Estimate ember production rate φ: (3622)
      1. Ember production rate depends on fuel type and torching/not torching
   iii. λ=φR where φ is the ember production rate and R is the current intensity of the node.
      1. If intensity is less than a critical threshold (~75% of maximum), no embers are produced.
      2. More intense combustion produces more embers. Ember generation rate is proportional to fire intensity.
   iv. Estimate the number of embers (3624) to simulate at this timestep by drawing from a poission distribution with the rate parameter A:
   v. Nₜ~Possion(λ)

For each simulated ember (i=1 . . . N) (3626):
i. Apply a random walk (3628) directional shift to derive the simulated wind direction vector:

$${ψ}_{i} = {ψ}_{0} + {\sum }_{k = 1}^{i} 𝒩 ( {μ}_{θ} , {σ}_{θ} ) .$$

i. Calculate the fraction of maximum transport distance (3630) of the ember:

$${d}_{i} ∼ Exponential ( α )$$

1. Where α is a developer-specified distribution parameter.
ii. Calculate a wind speed adjustment (3632):
   1. The effect of wind speed on ember transport is non-linear. At low wind speeds, ember transport is low; at high wind speeds, ember transport is significant. We introduce the wind speed adjustment to reflect the non-linear effects of wind speed on ember travel.
   2. Wind speed is a sigmoid function:

$$S ( u ) = \frac{{S}_{max}}{1 + exp [ - k ( u - c ) ]}$$

a. Where:
   i. Sₘₐₓ=0.5
   ii. k is a steepness parameter (0.3)
   iii. c is a centerpoint parameter (17.5)
ii. Calculate the potential transport distance (3634) of the ember:

$${\hat{D}}_{i} = {d}_{i} {D}_{max}$$

1. Where Dₘₐₓ is a developer-specified maximum distance parameter. Maximum distance is a function of structure/vegetation and torching/not torching and topographic position index.
ii. Calculate the actual transport distance (3636) of the ember:

$${D}_{i} = uS ( u ) {\tilde{D}}_{i}$$

1. Where u is the wind speed, S(u) is the non-linear wind adjustment factor, and Dₘₐₓ is the maximum potential transport distance.
ii. Calculate the final landing location (3638) of each ember:
   1. Given the ember-specific wind vector (speed and direction):

$${\hat{w}}_{i} = ( cos {ψ}_{i} , sin {ψ}_{i} ) .$$

$$Calculate the landing location of the ember :$$

$${x}_{i}^{′} = x + {\hat{w}}_{z , i} , {D}_{i} , {y}_{i}^{′} = y + {\hat{w}}_{y , i} {D}_{i}$$

1. In simple terms,
   a. the ember starts at (x,y) and moves Dᵢ units in direction ψᵢ.
   b. Dᵢ represents exponential decay with distance, the non-linear effects of wind speed, and a maximum potential distance specific to fuel type and torching/not torching.
b. ψᵢ represents a noisy wind vector that incorporates random directional noise
c. Target computation (3640):
   i. The landing locations x′ and y′ are compared (3642) to the locations of each unburned node in the graph.
d. Determine (3644) if the ember lands within 5 m of a structure node, that structure is considered for ignition
   1. If the ember lands within 20 m of a vegetation node, that structure is considered for ignition. While this seems like a greater threat radius, each vegetation node represents a patch of vegetation (i.e., we don't have “footprints” for vegetation), so it ends up being about the same.

### 5.11 Receptivity

Receptivity is a property of each node that describes how easily it ignites when exposed to fire.

In the XFM model, there are several types of receptivity (ember, surface, direct flame), each reflecting a different ignition mechanism.
a. These should be thought of as scaling parameters, not absolute probabilities—because the fire evolves over multiple timesteps, nodes will be likely be exposed to fire from the same source at multiple consecutive timesteps.
b. Therefore, the total probability of ignition of a node along a given edge is the likelihood of ignition from at least one exposure, where those exposures are weighted by these receptivity parameters.

If the per-timestep likelihood is

$${p}_{t} = R \cdot {E}_{t} ,$$

Where:
a. R is the node's receptivity parameter to that mechanism of fire exposure (e.g., ember receptivity, surface spread receptivity)
b. Eₜ is the timestep's probability of ignition along the given edge

Then, the total probability of ignition along that edge is

$${P}_{ignite} = 1 - {\prod }_{t = 1}^{T} ( 1 - {p}_{t} ) ,$$

Where:
a. T is the total number of timesteps where pₜ>0.
b. P_{ignite} is the probability of at least one successful ignition event across all timesteps.

### Vegetation Nodes:

a. Ember: Receptivity of vegetation nodes to ignition once an ember has been deposited on that node. Default value 0.05. Default value matches the FARSITE default value.
b. Surface: Receptivity of vegetation nodes to ignition from adjacent surface fire. Default value 0.9.

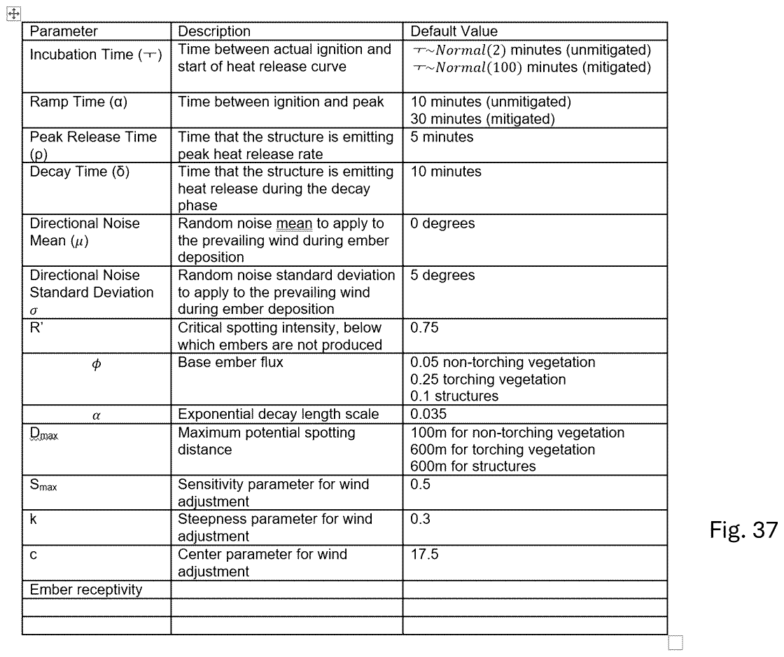

FIG. 37 is a table of parameters that may be configurable by the model developer.

### 6.0 Still Other Observations

In recent pilot studies, we have been running about 300-700 simulations per community (e.g., Mill Valley, CA). These simulations are based on 10-20 different ignition locations, yielding about 25 runs per ignition point. More simulations provide a better assessment of potential outcomes. From observation, increasing the number of runs beyond about 20-30 does not meaningfully change the patterns of risk derived from the model; however, it does change the exact outcome probabilities for each node as the ensemble converges.

We use a node-based graph because it allows the fire model to explicitly represent relationships rather than adjacent pixels, providing a realistic representation of ignition mechanics, causal ignition chains, and flexible discontinuities (roads, non-burnable areas, mitigation zones). Raster-based systems cannot represent these mechanics.

Radiant Heat Transfer: In the preferred embodiments, radiative heat transfer follows the Stefan-Boltzmann law; received flux decreases with distance squared. Empirical studies show that the ignition probability is near 100% within ~5-8 m of a structure emitting peak HRR; structures located further away have a much lower probability of ignition.

The fire model uses a probability of ignition proportional to an exponential distance-decay function, which preserves the shape of the physical process without requiring expensive CFD calculations.
Convective Heat Transfer: Convective heating depends on wind alignment and the direction of hot gas transport. The model converts the angular dependence of plume-driven heating into a cosine-like probability function, yielding maximum ignition probability when the bearing matches the wind direction. This approach matches known relationships between wind alignment and convective heating reach.
Surface Fire Spread: Surface fire spread into vegetation or from landscaping fuels employs the standard Rothermel ROS equations. Deterministic rates of spread along the edge are paired with a receptivity factors reflecting the target node's propensity to ignite. Receptivity values are aligned with FARSITE's standard assumptions (high receptivity in vegetative fuels) and modified to reflect defensible space and home hardening's capacity to change a structure's receptivity to fire.
Ember Production, Transport, and Deposition: Embers are handled through a stochastic kernel-based spotting submodel. Using a parameterized statistical distribution for firebrand deposition is common practice. Representing transport as a parameterized process incorporating fire intensity, wind speed and direction, and wind characteristics is a technique used in other contexts.
Structure Fire Development: The use of fire development curves is widely accepted in fire suppression and in post-earthquake fire modeling and are based on empirical study.

The temporal resolution of some embodiments is 1 minute. The timestamp duration may be an adjustable). Within a single timestep, the different ignition modules are executed in sequence (RCH→Surface Fire→ember transport and deposition). If multiple mechanisms could create an ignition, the first to do so “wins” the ignition of that node. There is no partial credit or nuanced selection logic.

Mechanism frequency is illustrated through an ensemble approach, where the different ignition mechanisms are evaluated over multiple realizations of fire spread.

While the models described above attempt to parameterize turbulence and chaotic near-surface winds, there are additional dimensions that could be added such as vertical motion, eddies, and terrain, canopy, and building sheltering.

Nodes represent an area. Structure nodes are building footprints; vegetation nodes represent “patches” of vegetation.

Nodes can be exposed to an upstream fire spread mechanism for several timesteps. Each of these timesteps comes with a probability of ignition to the target building. As conditions change (fuel is consumed along the edge, the upstream structure fire develops, etc), the probability of ignition to the target structure changes. Ultimately, the edge will exhaust itself or the adjacent structure will burn out, rendering that mechanism of exposure inactive.

The dependency tree shows the progression of a single realization of fire spread over a given period of time from a given ignition location. This is not the theoretical fastest travel path.

However, it reflects the potential dependent relationships between nodes that aren't captured in a strict shortest-path solution, particularly when paired with ensemble outputs.

### 7.0 Other Implementation Options

It should be understood that the example embodiments described above may be implemented in many different ways. In some instances, the various “data processors” may each be implemented by a physical or virtual general purpose computer having a central processor, memory, disk or other mass storage, communication interface(s), input/output (I/O) device(s), and other peripherals. The general-purpose computer is transformed into the processors and executes the processes described above, for example, by loading software instructions into the processor, and then causing execution of the instructions to carry out the functions described.

As is known in the art, such a computer may contain a system bus, where a bus is a set of hardware lines used for data transfer among the components of a computer or processing system. The bus or busses are essentially shared conduit(s) that connect different elements of the computer system. One or more central processor units are attached to the system bus and provide for the execution of computer instructions. Also attached to system bus are typically I/O device interfaces for connecting disks, memories, and various input and output devices. Network interface(s) allow connections to various other devices. One or more memories provide volatile and/or non-volatile storage for computer software instructions and data used to implement an embodiment. Disks or other mass storage provides non-volatile storage for computer software instructions and data used to implement, for example, the various procedures described herein.

Embodiments may therefore typically be implemented in hardware, custom designed semiconductor logic, Application Specific Integrated Circuits (ASICs), Field Programmable Gate Arrays (FPGAs), firmware, software, or any combination thereof.

In certain embodiments, the procedures, devices, and processes described herein are a computer program product, including a computer readable medium (e.g., a removable storage medium such as one or more DVD-ROM's, CD-ROM's, diskettes, tapes, etc.) that provides at least a portion of the software instructions for the system. Such a computer program product can be installed by any suitable software installation procedure, as is well known in the art. In another embodiment, at least a portion of the software instructions may also be downloaded over a cable, communication and/or wireless connection.

Embodiments may also be implemented as instructions stored on a non-transient machine-readable medium, which may be read and executed by one or more procedures. A non-transient machine-readable medium may include any mechanism for storing or transmitting information in a form readable by a machine (e.g., a computing device). For example, a non-transient machine-readable medium may include read only memory (ROM); random access memory (RAM); storage including magnetic disk storage media; optical storage media; flash memory devices; and others.

Furthermore, firmware, software, routines, or instructions may be described herein as performing certain actions and/or functions. However, it should be appreciated that such descriptions contained herein are merely for convenience and that such actions in fact result from computing devices, processors, controllers, or other devices executing the firmware, software, routines, instructions, etc.

The above description included an explanation of several example embodiments. It should be understood that while a particular feature may have been disclosed with respect to only one of several embodiments, that particular feature may be combined with one or more other features of the other embodiments as may be desired and advantageous for any given or particular application. It is, of course, not possible to describe every conceivable combination of components or methodologies for purposes of describing the innovations herein, and one skill in the art may now, in light of the above description, recognize that many further combinations and permutations are possible. Also, to the extent that the terms “includes,” and “including” and variants thereof are used in either the detailed description or the claims, these terms are intended to be inclusive in a manner similar to the term “comprising”.

It also should be understood that the block and flow diagrams may include more or fewer elements, be arranged differently, or be represented differently. The computing devices, processors, controllers, firmware, software, routines, or instructions as described herein may also perform only certain selected actions and/or functions. Therefore, it will be appreciated that any such descriptions that designate one or more such components as providing only certain functions are merely for convenience.

When a series of steps has been described above with respect to the flow diagrams, the order of the steps may be modified in other implementations. In addition, the operations and steps may be performed by additional or other modules or entities, which may be combined or separated to form other modules or entities. For example, while a series of steps has been described with regard to certain figures, the order of the steps may be modified in other implementations consistent with the principles explained herein. Further, non-dependent steps may be performed in parallel. Further, disclosed implementations may not be limited to any specific combination of hardware.

No element, act, or instruction used herein should be construed as critical or essential to the disclosure unless explicitly described as such. Also, as used herein, the article “a” is intended to include one or more items. Where only one item is intended, the term “one” or similar language is used. Further, the phrase “based on” is intended to mean “based, at least in part, on” unless explicitly stated otherwise.

Accordingly, the subject matter covered by this patent is intended to embrace all such alterations, modifications, equivalents, and variations that fall within the spirit and scope of the claims that follow.

1. A computer-implemented method for prioritizing wildfire risk reduction activities for an urban environment, comprising:
obtaining urban environment data including (i) building structure data, (ii) structure separation distance data, (iii) ember transport data, and (iv) environmental condition data;
constructing a directed graph representing the urban environment, wherein nodes represent building structures and edges represent potential fire transmission between building structures and wherein the edge further include edge attributes comprising at least separation distance and compass bearing;
executing, by one or more processors, a probabilistic fire spread simulation over the directed graph that accounts for (a) structure ignition, (b) time-varying structure fire intensity, (c) radiant and or convective heat transmission, and (d) one or more of ember launch, transport, deposition, and ember-based ignition;
generating wildfire spread prediction data including a per-structure ignition probability; and
determining a resource-constrained treatment plan that selects, for a subset of the building structures, one or more mitigation actions to maximize a risk reduction metric derived from the wildfire spread prediction data.

2. The method of claim 1, wherein each node includes node attributes comprising home hardening status, defensible space status, and a firefighter presence indicator that modifies a probability of ignition of the corresponding building structure and further used in determining the mitigation actions.

3. The method of claim 1, wherein an edge is added between two nodes only when the separation distance between the corresponding building structures is less than a heat-transfer threshold distance, and wherein ember-based ignition is simulated for building structures separated by distances greater than the heat-transfer threshold distance.

4. The method of claim 1, wherein the edge attributes further comprise a road-crossing indicator indicating whether a line segment between the building structures crosses a road.

5. The method of claim 4, wherein the simulation models at least a surface fire spread mechanism that is disabled for edges crossing a road while radiant/convective heating and ember-based ignition remain enabled for the edges crossing the road.

6. The method of claim 1, wherein the simulation computes a radiant heating ignition probability that decays non-linearly with separation distance and is scaled based on current fire intensity of a source building structure.

7. The method of claim 1, wherein the simulation computes a convective heating ignition probability that is scaled based on alignment between an edge bearing and a prevailing wind direction and further scaled based on slope.

8. The method of claim 1, wherein the time-varying structure fire intensity comprises a ramp-up phase, a peak intensity phase, and a decay phase, and wherein ember launch probability increases toward the peak intensity phase.

9. The method of claim 1, wherein ember trajectories are simulated using prevailing wind speed and wind direction with randomized perturbations, and deposition locations are compared to building footprints to determine ember-based ignitions.

10. The method of claim 1, further comprising simulating ambient embers generated from non-structure wildland fire pathways at a background rate and transported to the urban environment to determine additional structure ignitions.

11. The method of claim 1, wherein the per-structure ignition probability is computed from an ensemble of simulation runs as a frequency of ignition of each node across the ensemble.

12. The method of claim 11, further comprising generating, from at least one simulation run or from the ensemble, a dependency tree or Markov-type transition model linking upstream ignitions to downstream ignitions.

13. The method of claim 1, wherein determining the treatment plan comprises iteratively selecting candidate mitigation actions based on marginal risk reduction attributable to each candidate mitigation action.

14. The method of claim 13, wherein the iterative selection is further based on a centrality measure of nodes in the directed graph.

15. A system for prioritizing wildfire risk reduction activities for an urban environment, comprising: one or more processors; and memory storing instructions that, when executed by the one or more processors, cause the system to perform the method of claim 1.

16. The system of claim 15, wherein the instructions cause ingesting sensed wind direction data to update at least one of convective heating ignition probabilities and ember trajectory simulations.

17. The system of claim 15, further comprising a user interface that renders a map depicting the per-structure ignition probability and outputs the treatment plan as a rank-ordered list of structures for mitigation.

18. The system of claim 15, wherein the resource constraint comprises a predefined number of structures to be treated or a budget constraint.

19. A non-transitory computer-readable medium storing instructions that, when executed by one or more processors, performs the method of claim 1.

20. The non-transitory computer-readable medium of claim 19, wherein the instructions further cause calibrating probabilistic ignition parameters based on historical urban conflagration data.
